(19) United States
(12) Patent Application Publication
(10) Pub. No.: US 2024/0190756 A1
(43) Pub. Date: Jun. 13, 2024

(54) LOW-MODULUS ION-EXCHANGEABLE GLASS COMPOSITIONS

(71) Applicant: CORNING INCORPORATED, CORNING, NY (US)

(72) Inventors: TIMOTHY MICHAEL GROSS, PAINTED POST, NY (US); JINGSHI WU, PAINTED POST, NY (US)

(21) Appl. No.: 18/286,889

(22) PCT Filed: Apr. 13, 2022
(86) PCT No.: PCT/US2022/024619

§ 371 Date: Oct. 13, 2023

Related U.S. Application Data
(60) Provisional application No. 63/177,536, filed on Apr. 21, 2021.

(51) Int. Cl. C03C 3/091; C03C 3/097; C03C 21/00; H05K 5/03

(52) U.S. Cl. CPC C03C 3/091; C03C 3/097; C03C 21/002; H05K 5/03

(57) ABSTRACT

A glass composition includes from 40 mol % to 56.5 mol % SiO₂; from 10 mol % to 25 mol % Al₂O₃; from 12 mol % to 35 mol % B₂O₃; from 9 mol % to 14.75 mol % Na₂O; from 0 mol % to 5 mol % K₂O; and from 0 mol % to 3 mol % Li₂O. The sum of Na₂O, K₂O, and Li₂O (i.e., R₂O) in the glass composition may be from 9 mol % to 19 mol %. (R₂O—Al₂O₃)/B₂O₃ in the glass composition may be less than or equal to 0.25. R₂O/Al₂O₃ in the glass composition may be from 0.8 to 1.5.

### CROSS-REFERENCE TO RELATED APPLICATION

This application claims the benefit of priority under 35 U.S.C. § 119 of U.S. Provisional Application Ser. No. 63/177,536 filed on Apr. 21, 2021, the content of which is relied upon and incorporated herein by reference in its entirety.

### FIELD

The present specification generally relates to ion-exchangeable glass compositions and, in particular, to ion-exchangeable glass compositions capable of providing low-modulus glass articles for cover glass applications, for example, a cover glass for a flexible display.

### TECHNICAL BACKGROUND

Many consumer products, for example smart phones, tablets, portable media players, personal computers, and cameras, incorporate cover glasses that may function as display covers, and may incorporate touch functionality. Frequently, these devices are dropped by users onto hard surfaces, which can cause damage to the cover glasses, and may negatively impact the use of the devices, for example, the touch functionality may be compromised.

Foldable or flexible displays for consumer electronics applications may benefit from thin, flexible ion-exchanged glass articles. Glass articles may be made more resistant to flexure failure through ion-exchange processes, which involve inducing compressive stresses on the glass surfaces. The compressive stress introduced using an ion-exchange process serves to, among other things, arrest flaws that can cause failure of the glass article.

Therefore, a continuing need exists for ion-exchangeable glass compositions having desirable mechanical properties for use in a variety of applications, including cover glass applications.

### SUMMARY

According to a first aspect A1, a glass composition may comprise: greater than or equal to 40 mol % and less than or equal to 56.5 mol % SiO₂; greater than or equal to 10 mol % and less than or equal to 25 mol % Al₂O₃; greater than or equal to 12 mol % and less than or equal to 35 mol % B₂O₃; greater than or equal to 9 mol % and less than or equal to 14.75 mol % Na₂O; greater than or equal to 0 mol % and less than or equal to 5 mol % K₂O; and greater than or equal to 0 mol % and less than or equal to 3 mol % Li₂O, wherein R₂O is greater than or equal to 9 mol % and less than or equal to 19 mol %, wherein R₂O is the sum of Na₂O, K₂O, and Li₂O; (R₂O—Al₂O₃)/B₂O₃ is less than or equal to 0.25; and R₂O/Al₂O₃ is greater than or equal to 0.8 and less than or equal to 1.5.

A second aspect A2 includes the glass composition according to the first aspect A1, wherein the glass composition comprises greater than or equal to 13 mol % and less than or equal to 30 mol % B₂O₃.

A third aspect A3 includes the glass composition according to the second aspect A2, wherein the glass composition comprises greater than or equal to 18.5 mol % and less than or equal to 30 mol % B₂O₃.

A fourth aspect A4 includes the glass composition according to any one of the first aspect A1 to third aspect A3, wherein the glass composition comprises greater than or equal to 9.5 mol % and less than or equal to 14.5 mol % Na₂O.

A fifth aspect A5 includes the glass composition according to the fourth aspect A4, wherein the glass composition comprises greater than or equal to 10 mol % and less than or equal to 14.25 mol % Na₂O.

A sixth aspect A6 includes the glass composition according to any one of the first aspect A1 to fifth aspect A5, wherein the glass composition comprises greater than or equal to 10.5 mol % and less than or equal to 23 mol % Al₂O₃.

A seventh aspect A7 includes the glass composition according to the sixth aspect A6, wherein the glass composition comprises greater than or equal to 15 mol % and less than or equal to 23 mol % Al₂O₃.

An eighth aspect A8 includes the glass composition according to any one of the first aspect A1 to seventh aspect A7, wherein (R₂O—Al₂O₃)/B₂O₃ is greater than or equal to −0.15 and less than or equal to 0.25.

A ninth aspect A9 includes the glass composition according to the eighth aspect A8, wherein (R₂O—Al₂O₃)/B₂O₃ is greater than or equal to −0.05 and less than or equal to 0.2.

A tenth aspect A10 includes the glass composition according to any one of the first aspect A1 to ninth aspect A9, wherein R₂O/Al₂O₃ is greater than or equal to 0.85 and less than or equal to 1.45.

An eleventh aspect A11 includes the glass composition according to the tenth aspect A10, wherein R₂O/Al₂O₃ is greater than or equal to 0.9 and less than or equal to 1.4.

A twelfth aspect A12 includes the glass composition according to any one of the first aspect A1 to eleventh aspect A11, wherein R₂O is greater than or equal to 9.5 mol % and less than or equal to 18.5 mol %.

A thirteenth aspect A13 includes the glass composition according to any one of the first aspect A1 to twelfth aspect A12, wherein the glass composition comprises greater than or equal to 0 mol % and less than or equal to 5 mol % P₂O₅.

A fourteenth aspect A14 includes the glass composition according to any one of the first aspect A1 to thirteenth aspect A13, wherein the glass composition is free or substantially free of Li₂O, MgO, CaO, ZnO, ZrO₂, or combinations thereof.

A fifteenth aspect A15 includes the glass composition according to any one of the first aspect A1 to fourteenth aspect A14, wherein the glass composition comprises greater than or equal to 0 mol % and less than or equal to 0.1 mol % SnO₂.

According to a sixteenth aspect A16, a glass article may comprise: greater than or equal to 40 mol % and less than or equal to 56.5 mol % SiO₂; greater than or equal to 10 mol % and less than or equal to 25 mol % Al₂O₃; greater than or equal to 12 mol % and less than or equal to 35 mol % B₂O₃; greater than or equal to 9 mol % and less than or equal to 14.75 mol % Na₂O; greater than or equal to 0 mol % and less than or equal to 5 mol % K₂O; and greater than or equal to 0 mol % and less than or equal to 3 mol % Li₂O, wherein R₂O is greater than or equal to 9 mol % and less than or equal to 19 mol %, wherein R₂O is the sum of Na₂O, K₂O, and Li₂O; (R₂O—Al₂O₃)/B₂O₃ is less than or equal to 0.25; R₂O/Al₂O₃ is greater than or equal to 0.8 and less than or equal to 1.5; and a Young's modulus of the glass article, before being ion-exchanged, is greater than or equal to 40 GPa and less than or equal to 70 GPa.

A seventeenth aspect A17 includes the glass article according to the sixteenth aspect A16, wherein the Young's modulus of the glass article, before being ion-exchanged, is greater than or equal to 45 GPa and less than or equal to 68 GPa.

An eighteenth aspect A18 includes the glass article according to the sixteenth aspect A16 or the seventeenth aspect A17, wherein a liquidus viscosity of the glass article, before being ion-exchanged, is greater than or equal to 50 kP.

A nineteenth aspect A19, includes the glass article according to any one of the sixteenth aspect A16 to eighteenth aspect A18, wherein a peak compressive stress of the glass article is greater than or equal to 400 MPa and less than or equal to 900 MPa.

A twentieth aspect A20, includes the glass article according the nineteenth aspect A19, wherein the peak compressive stress of the glass article is greater than or equal to 450 MPa and less than or equal to 850 MPa.

A twenty-first aspect A21, includes the glass article according to any one of the sixteenth aspect A16 to twentieth aspect A20, wherein a thickness of the glass article is greater than or equal to 35 μm and less than or equal to 400 μm and a depth of compression of the glass article is greater than or equal to 5 μm and less than or equal to 40 μm.

A twenty-second aspect A22 includes the glass article according to the twenty-first aspect A21, wherein the depth of compression of the glass article is greater than or equal to 10 μm and less than or equal to 35 μm.

A twenty-third aspect A23 includes the glass article according to any one of the sixteenth aspect A16 to twenty-second aspect A22, wherein a depth of compression of the glass article is greater than or equal to 5% and less than or equal to 20% of a thickness of the glass article.

A twenty-fourth aspect A24 includes the glass article according to any one of the sixteenth aspect A16 to twenty-third aspect A23, wherein a peak central tension of the glass article is greater than or equal to 200 MPa and less than or equal to 450 MPa.

A twenty-fifth aspect A25 includes the glass article according to any one of the sixteenth aspect A16 to twenty-fourth aspect A24, wherein the glass article is bent to a platen spacing of 7.12 mm and a peak central tension of the bent glass article is greater than or equal to 340 MPa and less than or equal to 450 MPa at an article thickness of 50 μm.

According to a twenty-sixth aspect A26, a consumer electronic device may comprise: a housing having a front surface, a back surface, and side surfaces; electrical components provided at least partially within the housing, the electrical components including at least a controller, a memory, and a display, the display being provided at or adjacent the front surface of the housing; and the glass article of any one of the sixteenth aspect A16 to the twenty-fourth aspect A24 disposed over the display.

According to a twenty-seventh aspect A27, a method fo strengthening a glass article may comprise: immersing the glass article in an ion-exchange solution, the glass article comprising: greater than or equal to 40 mol % and less than or equal to 56.5 mol % SiO₂; greater than or equal to 10 mol % and less than or equal to 25 mol % Al₂O₃; greater than or equal to 12 mol % and less than or equal to 35 mol % B₂O₃; greater than or equal to 9 mol % and less than or equal to 14.75 mol % Na₂O; greater than or equal to 0 mol % and less than or equal to 5 mol % K₂O; and greater than or equal to 0 mol % and less than or equal to 3 mol % Li₂O, wherein R₂O is greater than or equal to 9 mol % and less than or equal to 19 mol %, wherein R₂O is the sum of Na₂O, K₂O, and Li₂O; (R₂O—Al₂O₃)/B₂O₃ is less than or equal to 0.25; and R₂O/Al₂O₃ is greater than or equal to 0.8 and less than or equal to 1.5; ion-exchanging the glass article in the ion-exchange solution for a time period greater than or equal to 1 hour and less than or equal to 24 hours at a temperature greater than or equal to 350° C. and less than or equal to 480° C. to achieve a compressive stress layer extending from a surface of the glass article to a depth of compression and comprising a peak compressive stress value in a range of 400 MPa to 900 MPa.

A twenty-eighth aspect A28 includes the method according to the twenty-seventh aspect A27, wherein a thickness of the glass article is greater than or equal to 35 μm and less than or equal to 400 μm and a depth of compression of the glass article is greater than or equal to 5 μm and less than or equal to 40 μm.

A twenty-ninth aspect A29 includes the method according to the twenty-seventh aspect A27 or the twenty-eighth aspect A28, wherein a peak compressive stress of the glass article is greater than or equal to 400 MPa and less than or equal to 900 MPa.

A thirtieth aspect A30 includes the method according to any one of the twenty-seventh aspect A27 to twenty-ninth aspect A29, wherein the Young's modulus of the glass article, before being ion-exchanged, is greater than or equal to 40 GPa and less than or equal to 70 GPa.

A thirty-first aspect A31 includes the method according any one of the twenty-seventh aspect A27 to the thirtieth aspect A30, wherein a peak central tension of the glass article is greater than or equal to 200 MPa and less than or equal to 450 MPa.

A thirty-second aspect A32 includes the method according to any one of the twenty-seventy aspect A27 to the thirty-first aspect A31, wherein the glass article is bent to a platen spacing of 7.12 mm and a peak central tension of the bent glass article is greater than or equal to 340 MPa and less than or equal to 450 MPa at an article thickness of 50 μm.

Additional features and advantages of the glass compositions described herein will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is a cross-sectional, schematic view of a glass article having compressive stress regions according to one or more embodiments described herein;

FIG. 2 is a cross-sectional, schematic view of a glass article under bend-induced stress;

FIG. 3 is a plot showing superposition of ion-exchange and bend-induced stresses in a glass article under bend-induced stress;

FIG. 4 is a plan view of an electronic device incorporating any of the glass articles according to one or more embodiments described herein;

FIG. 5 is a perspective view of the electronic device of FIG. 4.

### DETAILED DESCRIPTION

Reference will now be made in detail to various embodiments of ion-exchangeable glass compositions having a relatively low Young's modulus. According to embodiments, a glass composition includes greater than or equal to 40 mol % and less than or equal to 56.5 mol % SiO₂; greater than or equal to 10 mol % and less than or equal to 25 mol % Al₂O₃; greater than or equal to 12 mol % and less than or equal to 35 mol % B₂O₃; greater than or equal to 9 mol % and less than or equal to 14.75 mol % Na₂O; greater than or equal to 0 mol % and less than or equal to 5 mol % K₂O; and greater than or equal to 0 mol % and less than or equal to 3 mol % Li₂O. The sum of Na₂O, K₂O, and Li₂O (i.e., R₂O) in the glass composition may be greater than or equal to 9 mol % and less than or equal to 19 mol %. (R₂O—Al₂O₃)/B₂O₃ in the glass composition may be less than or equal to 0.25. R₂O/Al₂O₃ in the glass composition may be is greater than or equal to 0.8 and less than or equal to 1.5. Various embodiments of ion-exchangeable glass compositions and methods of strengthening low-modulus glass articles formed therefrom will be described herein with specific reference to the appended drawings.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made only with reference to the figures as drawn and are not intended to imply absolute orientation.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural referents unless the context clearly dictates otherwise. Thus, for example, reference to “a” component includes aspects having two or more such components, unless the context clearly indicates otherwise.

In the embodiments of the glass compositions described herein, the concentrations of constituent components (e.g., SiO₂, Al₂O₃, and the like) are specified in mole percent (mol %) on an oxide basis, unless otherwise specified.

The term “substantially free,” when used to describe the concentration and/or absence of a particular constituent component in a glass composition, means that the constituent component is not intentionally added to the glass composition. However, the glass composition may contain traces of the constituent component as a contaminant or tramp in amounts of less than 0.1 mol %.

The terms “0 mol %” and “free,” when used to describe the concentration and/or absence of a particular constituent component in a glass composition, means that the constituent component is not present in glass composition.

The term “fracture toughness,” as used herein, refers to the K_{Ic} value, and is measured by the chevron notched short bar method. The chevron notched short bar (CNSB) method is disclosed in Reddy, K. P. R. et al, “Fracture Toughness Measurement of Glass and Ceramic Materials Using Chevron-Notched Specimens,” J. Am. Ceram. Soc., 71 [6], C-310-C-313 (1988) except that Y*ₘ is calculated using equation 5 of Bubsey, R. T. et al., “Closed-Form Expressions for Crack-Mouth Displacement and Stress Intensity Factors for Chevron-Notched Short Bar and Short Rod Specimens Based on Experimental Compliance Measurements,” NASA Technical Memorandum 83796, pp. 1-30 (October 1992). Fracture toughness values as reported herein were measured on non-ion-exchanged glass, i.e., the composition existing prior to any ion-exchange processes were carried out on the glass.

The term “Vogel-Fulcher-Tamman (‘VFT’) relation,” as used herein, describes the temperature dependence of the viscosity and is represented by the following equation:

$$log η = A + \frac{B}{T - {T}_{o}}$$

where η is viscosity. To determine VFT A, VFT B, and VFT Tₒ, the viscosity of the glass composition is measured over a given temperature range. The raw data of viscosity versus temperature is then fit with the VFT equation by least-squares fitting to obtain A, B, and Tₒ. With these values, a viscosity point (e.g., 200 P Temperature, 35 k P Temperature, and 200 k P Temperature) at any temperature above softening point may be calculated.

The term “melting point,” as used herein, refers to the temperature at which the viscosity of the glass composition is 200 poise as measured in accordance with ASTM C338.

The term “softening point,” as used herein, refers to the temperature at which the viscosity of the glass composition is 1×10^{7.6} poise. The softening point is measured according to the parallel plate viscosity method which measures the viscosity of inorganic glass from 10⁷ to 10⁹ poise as a function of temperature, similar to ASTM C1351M.

The term “annealing point” or “effective annealing temperature” as used herein, refers to the temperature at which the viscosity of the glass composition is 1×10^{13.18} poise as measured in accordance with ASTM C598.

The term “strain point,” as used herein, refers to the temperature at which the viscosity of the glass composition is 1×10^{14.68} poise as measured in accordance with ASTM C598.

Density, as described herein, is measured by the buoyancy method of ASTM C693-93.

The term “CTE,” as used herein, refers to the instantaneous coefficient of thermal expansion of the glass composition at 300° C. cooling (i.e., the instantaneous CTE at 300° C., measured while cooling).

The term “liquidus viscosity,” as used herein, refers to the viscosity of the glass composition at the onset of devitrification (i.e., at the liquidus temperature as determined with the gradient furnace method according to ASTM C829-81).

The term “liquidus temperature,” as used herein, refers to the temperature at which the glass composition begins to devitrify as determined with the gradient furnace method according to ASTM C829-81.

The elastic modulus (also referred to as Young's modulus) of the glass composition, as described herein, is provided in units of gigapascals (GPa) and is measured in accordance with ASTM C623.

The shear modulus of the glass composition, as described herein, is provided in units of gigapascals (GPa). The shear modulus of the glass composition is measured in accordance with ASTM C623.

Poisson's ratio, as described herein, is measured in accordance with ASTM C623.

Refractive index, as described herein, is measured in accordance with ASTM E1967.

As used herein, “peak compressive stress” refers to the highest compressive stress (CS) value measured within a compressive stress region. In embodiments, the peak compressive stress is located at the surface of the glass article. In other embodiments, the peak compressive stress may occur at a depth below the surface, giving the compressive stress profile the appearance of a “buried peak.” Unless specified otherwise, compressive stress (including surface CS) is measured by surface stress meter (FSM) using commercially available instruments, for example, the FSM-6000, manufactured by Orihara Industrial Co., Ltd. (Japan). Surface stress measurements rely upon the accurate measurement of the stress optical coefficient (SOC) which is related to the birefringence of the glass article. SOC in turn is measured according to Procedure C (Glass Disk Method) described in ASTM C770-16, entitled “Standard Test Method for measurement of Glass Stress-Optical Coefficient.” The maximum central tension (CT) values are measured using a Scattered Light Polariscope (SCALP), such as a SCALP-05 portable scattered light polariscope. The values reports for central tension (CT) herein refer to the maximum central tension, unless otherwise indicated.

According to the convention normally used in the art, compression or compressive stress (CS) is expressed as a negative (i.e., <0) stress and tension or tensile stress is expressed as a positive (i.e., >0) stress. Throughout this description, however, CS is expressed as a positive or absolute value (i.e., as recited herein, CS=|CS|).

As used herein, “depth of compression” (DOC) refers to the depth at which the stress within the glass article changes from compressive to tensile. At the DOC, the stress crosses from a compressive stress to a tensile stress and thus exhibits a stress value of zero. Depth of compression may be measured using a Scattered Light Polariscope (SCALP), such as a SCALP-05 portable scattered light polariscope. As used herein, “depth of layer” (DOL) refers to the depth within a glass article at which an ion of metal oxide diffuses into the glass article where the concentration of the ion reaches a minimum value. DOL may be measured using electron probe microanalysis (EPMA).

Flexible versions of products and components that are traditionally rigid in nature are being conceptualized for new applications. For example, flexible electronic devices may provide thin, lightweight, and flexible properties that offer opportunities for new applications, for example, curved displays and wearable devices. Some of these electronic devices may also make use of flexible displays. Flexible displays should have resistance to failure at small bend radii, particularly for flexible displays that have touch screen functionality and/or may be folded. While conventional flexible glass articles are available for bending applications, such conventional articles may not provide the desired mechanical properties to enable tighter bending (i.e., small bend radii) without cracking and/or failure.

Disclosed herein are glass compositions which mitigate the aforementioned problems. Specifically, the glass compositions disclosed herein comprise a relatively high concentration of B₂O₃, which results in glass compositions having relatively low Young's modulus such that glass articles formed therefrom may subjected to relatively tighter bending. A relatively low Young's modulus also leads to a reduced central tension, which prevents fragmentation of the glass article into small pieces upon being bent, and reduced stress intensity, which prevents crack growth and glass failure.

The glass compositions described herein may be described as aluminoborosilicate glass compositions and comprise SiO₂, Al₂O₃, and B₂O₃. The glass compositions described herein also include alkali oxides, such as Na₂O, to enable the ion-exchangeability of the glass compositions.

SiO₂ is the primary glass former in the glass compositions described herein and may function to stabilize the network structure of the glass compositions. The concentration of SiO₂ in the glass compositions should be sufficiently high (e.g., greater than or equal to 40 mol %) to provide basic glass forming capability. The amount of SiO₂ may be limited (e.g., to less than or equal to 56.5 mol %) to control the melting point of the glass composition, as the melting temperature of pure SiO₂ or high SiO₂ glasses is undesirably high. Thus, limiting the concentration of SiO₂ may aid in improving the meltability and the formability of the glass composition.

Accordingly, in embodiments, the glass composition may comprise greater than or equal to 40 mol % and less than or equal to 56.5 mol % SiO₂. In embodiments, the concentration of SiO₂ in the glass composition may be greater than or equal to 40 mol %, greater than or equal to 42 mol %, greater than or equal to 44 mol %, or even greater than or equal to 46 mol %. In embodiments, the concentration of SiO₂ in the glass composition may be less than or equal to 56.5 mol %, less than or equal to 56 mol %, less than or equal to 54 mol %, or even less than or equal to 52 mol %. In embodiments, the concentration of SiO₂ in the glass composition may greater than or equal to 40 mol % and less than or equal to 56.5 mol %, greater than or equal to 40 mol % and less than or equal to 56 mol %, greater than or equal to 40 mol % and less than or equal to 54 mol %, greater than or equal to 40 mol % and less than or equal to 52 mol %, greater than or equal to 42 mol % and less than or equal to 56.5 mol %, greater than or equal to 42 mol % and less than or equal to 56 mol %, greater than or equal to 42 mol % and less than or equal to 54 mol %, greater than or equal to 42 mol % and less than or equal to 52 mol %, greater than or equal to 44 mol % and less than or equal to 56.5 mol %, greater than or equal to 44 mol % and less than or equal to 56 mol %, greater than or equal to 44 mol % and less than or equal to 54 mol %, greater than or equal to 44 mol % and less than or equal to 52 mol %, greater than or equal to 40 mol % and less than or equal to 56.5 mol %, greater than or equal to 46 mol % and less than or equal to 56 mol %, greater than or equal to 46 mol % and less than or equal to 54 mol %, or even greater than or equal to 46 mol % and less than or equal to 52 mol %, or any and all sub-ranges formed from any of these endpoints.

Like SiO₂, Al₂O₃ may also stabilize the glass network and additionally provides improved mechanical properties and chemical durability to the glass composition. The amount of Al₂O₃ may also be tailored to the control the viscosity of the glass composition. Al₂O₃ also charge balances Na₂O present in the glass composition by forming sodium aluminate (NaAlO₂), thereby keeping boron in a three-coordinate state, which helps to reduce the Young's modulus. The concentration of Al₂O₃ should be sufficiently high (e.g., greater than or equal to 10 mol %) such that the glass composition has the desired Young's modulus (e.g., greater than or equal to 40 GPa and less than or equal to 70 GPa). However, if the amount of Al₂O₃ is too high (e.g., greater than 25 mol %), the viscosity of the melt may increase, thereby diminishing the formability of the glass composition. In embodiments, the glass composition may comprise greater than or equal to 10 mol % and less than or equal to 25 mol % Al₂O₃. In embodiments, the glass composition may comprise greater than or equal to 10.5 mol % and less than or equal to 23 mol % Al₂O₃. In embodiments, the glass composition may comprise greater than or equal to 15 mol % and less than or equal to 23 mol % Al₂O₃. In embodiments, the concentration of Al₂O₃ in the glass composition may be greater than or equal to 10 mol %, greater than or equal to 10.5 mol %, greater than or equal to 11 mol %, greater than or equal to 11.5 mol %, greater than or equal to 12 mol %, greater than or equal to 12.5 mol %, or even greater than or equal to 13 mol %. In embodiments, the concentration of Al₂O₃ in the glass composition may be less than or equal to 25 mol %, less than or equal to 23 mol %, less than or equal to 20 mol %, less than or equal to 18 mol %, or even less than or equal to 16 mol %. In embodiments, the concentration of Al₂O₃ in the glass composition may be greater than or equal to 10 mol % and less than or equal to 25 mol %, greater than or equal to 10 mol % and less than or equal to 23 mol %, greater than or equal to 10 mol % and less than or equal to 20 mol %, greater than or equal to 10 mol % and less than or equal to 18 mol %, greater than or equal to 10 mol % and less than or equal to 16 mol %, greater than or equal to 10.5 mol % and less than or equal to 25 mol %, greater than or equal to 10.5 mol % and less than or equal to 23 mol %, greater than or equal to 10.5 mol % and less than or equal to 20 mol %, greater than or equal to 10.5 mol % and less than or equal to 18 mol %, greater than or equal to 10.5 mol % and less than or equal to 16 mol %, greater than or equal to 11 mol % and less than or equal to 25 mol %, greater than or equal to 11 mol % and less than or equal to 23 mol %, greater than or equal to 11 mol % and less than or equal to 20 mol %, greater than or equal to 11 mol % and less than or equal to 18 mol %, greater than or equal to 11 mol % and less than or equal to 16 mol %, greater than or equal to 11.5 mol % and less than or equal to 25 mol %, greater than or equal to 11.5 mol % and less than or equal to 23 mol %, greater than or equal to 11.5 mol % and less than or equal to 20 mol %, greater than or equal to 11.5 mol % and less than or equal to 18 mol %, greater than or equal to 11.5 mol % and less than or equal to 16 mol %, greater than or equal to 12 mol % and less than or equal to 25 mol %, greater than or equal to 12 mol % and less than or equal to 23 mol %, greater than or equal to 12 mol % and less than or equal to 20 mol %, greater than or equal to 12 mol % and less than or equal to 18 mol %, greater than or equal to 12 mol % and less than or equal to 16 mol %, greater than or equal to 12.5 mol % and less than or equal to 25 mol %, greater than or equal to 12.5 mol % and less than or equal to 23 mol %, greater than or equal to 12.5 mol % and less than or equal to 20 mol %, greater than or equal to 12.5 mol % and less than or equal to 18 mol %, greater than or equal to 12.5 mol % and less than or equal to 16 mol %, greater than or equal to 13 mol % and less than or equal to 25 mol %, greater than or equal to 13 mol % and less than or equal to 23 mol %, greater than or equal to 13 mol % and less than or equal to 20 mol %, greater than or equal to 13 mol % and less than or equal to 18 mol %, or even greater than or equal to 13 mol % and less than or equal to 16 mol %, or any and all sub-ranges formed from any of these endpoints.

B₂O₃ decreases the Young's modulus of the glass composition, which helps to reduce the central tension and stress intensity of a glass article formed therefrom. When the boron present is not charge balanced by alkali oxides (such as Na₂O, Li₂O and K₂O) or divalent cation oxides (such as MgO, CaO, SrO, BaO, and ZnO), the boron will be in a trigonal-coordinated state (or three-coordinated boron), which opens up the structure of the glass. The network around these three-coordinated boron atoms is not as rigid as tetrahedrally coordinated (or four-coordinated) boron. Without being bound by theory, it is believed that glass compositions that include three-coordinated boron can tolerate some degree of deformation (e.g., flexing and/or bending) before crack formation compared to four-coordinated boron. By tolerating some deformation, the Vickers indentation crack initiation threshold values increase. Fracture toughness of the glass compositions that include three-coordinated boron may also increase. B₂O₃ may also decrease the melting temperature of the glass composition.

The concentration of B₂O₃ should be sufficiently high (e.g., greater than or equal to 12 mol %) to improve the formability and decrease the Young's modulus of the glass composition. However, if B₂O₃ is too high, the chemical durability and liquidus viscosity may diminish and volatilization and evaporation of B₂O₃ during melting becomes difficult to control. Therefore, the amount of B₂O₃ may be limited (e.g., less than or equal to 35 mol %) to maintain chemical durability and manufacturability of the glass composition.

In embodiments, the glass composition may comprise greater than or equal to 12 mol % and less than or equal to 35 mol % B₂O₃. In embodiments, the glass composition may comprise greater than or equal to 13 mol % and less than or equal to 30 mol % B₂O₃. In embodiments, the glass composition may comprise greater than or equal to 18.5 mol % and less than or equal to 30 mol % B₂O₃. In embodiments, the concentration of B₂O₃ in the glass composition may be greater than or equal to 12 mol %, greater than or equal to 13 mol %, greater than or equal to 14 mol %, greater than or equal to 15 mol %, greater than or equal to 16 mol %, greater than or equal to 17 mol %, or even greater than or equal to 18.5 mol %. In embodiments, the concentration of B₂O₃ in the glass composition may be less than or equal to 35 mol %, less than or equal to 30 mol %, less than or equal to 28 mol %, less than or equal to 26 mol %, or even less than or equal to 24 mol %. In embodiments, the concentration of B₂O₃ in the glass composition may be greater than or equal to 12 mol % and less than or equal to 35 mol %, greater than or equal to 12 mol % and less than or equal to 30 mol %, greater than or equal to 12 mol % and less than or equal to 28 mol %, greater than or equal to 12 mol % and less than or equal to 26 mol %, greater than or equal to 12 mol % and less than or equal to 24 mol %, greater than or equal to 13 mol % and less than or equal to 35 mol %, greater than or equal to 13 mol % and less than or equal to 30 mol %, greater than or equal to 13 mol % and less than or equal to 28 mol %, greater than or equal to 13 mol % and less than or equal to 26 mol %, greater than or equal to 13 mol % and less than or equal to 24 mol %, greater than or equal to 14 mol % and less than or equal to 35 mol %, greater than or equal to 14 mol % and less than or equal to 30 mol %, greater than or equal to 14 mol % and less than or equal to 28 mol %, greater than or equal to 14 mol % and less than or equal to 26 mol %, greater than or equal to 14 mol % and less than or equal to 24 mol %, greater than or equal to 15 mol % and less than or equal to 35 mol %, greater than or equal to 15 mol % and less than or equal to 30 mol %, greater than or equal to 15 mol % and less than or equal to 28 mol %, greater than or equal to 15 mol % and less than or equal to 26 mol %, greater than or equal to 15 mol % and less than or equal to 24 mol %, greater than or equal to 16 mol % and less than or equal to 35 mol %, greater than or equal to 16 mol % and less than or equal to 30 mol %, greater than or equal to 16 mol % and less than or equal to 28 mol %, greater than or equal to 16 mol % and less than or equal to 26 mol %, greater than or equal to 16 mol % and less than or equal to 24 mol %, greater than or equal to 17 mol % and less than or equal to 35 mol %, greater than or equal to 17 mol % and less than or equal to 30 mol %, greater than or equal to 7 mol % and less than or equal to 28 mol %, greater than or equal to 17 mol % and less than or equal to 26 mol %, greater than or equal to 17 mol % and less than or equal to 24 mol %, greater than or equal to 18.5 mol % and less than or equal to 35 mol %, greater than or equal to 18.5 mol % and less than or equal to 30 mol %, greater than or equal to 18.5 mol % and less than or equal to 28 mol %, greater than or equal to 18.5 mol % and less than or equal to 26 mol %, or even greater than or equal to 18.5 mol % and less than or equal to 24 mol %, or any and all sub-ranges formed from any of these endpoints.

As described hereinabove, the glass compositions may contain alkali oxides, such as Na₂O, to enable the ion-exchangeability of the glass compositions. Na₂O aids in the ion-exchangeability of the glass composition and also reduces the softening point of the glass composition thereby increasing the formability of the glass. In embodiments, the glass composition may comprise greater than or equal to 9 mol % and less than or equal to 14.75 mol % Na₂O. In embodiments, the glass composition may comprise greater than or equal to 9.5 mol % and less than or equal to 14.5 mol % Na₂O. In embodiments, the glass composition may comprise greater than or equal to 10 mol % and less than or equal to 14.25 mol % Na₂O. In embodiments, the concentration of Na₂O present in the glass composition may be greater than or equal to 9 mol %, greater than or equal to 9.5 mol %, greater than or equal to 10 mol %, greater than or equal to 10.5 mol %, greater than or equal to 11 mol %, greater than or equal to 11.5 mol %, or even greater than or equal to 12 mol %. In embodiments, the concentration of Na₂O present in the glass composition may be less than or equal to 14.75 mol %, less than or equal to 14.5 mol %, or even less than or equal to 14.25 mol %. In embodiments, the concentration of Na₂O present in the glass composition may be greater than or equal to 9 mol % and less than or equal to 14.75 mol %, greater than or equal to 9 mol % and less than or equal to 14.5 mol %, greater than or equal to 9 mol % and less than or equal to 14.25 mol %, greater than or equal to 9.5 mol % and less than or equal to 14.75 mol %, greater than or equal to 9.5 mol % and less than or equal to 14.5 mol %, greater than or equal to 9.5 mol % and less than or equal to 14.25 mol %, greater than or equal to 10 mol % and less than or equal to 14.75 mol %, greater than or equal to 10 mol % and less than or equal to 14.5 mol %, greater than or equal to 10 mol % and less than or equal to 14.25 mol %, greater than or equal to 10.5 mol % and less than or equal to 14.75 mol %, greater than or equal to 10.5 mol % and less than or equal to 14.5 mol %, greater than or equal to 10.5 mol % and less than or equal to 14.25 mol %, greater than or equal to 11 mol % and less than or equal to 14.75 mol %, greater than or equal to 11 mol % and less than or equal to 14.5 mol %, greater than or equal to 11 mol % and less than or equal to 14.25 mol %, greater than or equal to 11.5 mol % and less than or equal to 14.75 mol %, greater than or equal to 11.5 mol % and less than or equal to 14.5 mol %, greater than or equal to 11.5 mol % and less than or equal to 14.25 mol %, greater than or equal to 12 mol % and less than or equal to 14.75 mol %, greater than or equal to 12 mol % and less than or equal to 14.5 mol %, or even greater than or equal to 12 mol % and less than or equal to 14.25 mol %, or any and all sub-ranges formed from any of these endpoints.

The glass compositions described herein may further comprise alkali metal oxides other than Na₂O, such as K₂O and Li₂O. K₂O, when included, promotes ion-exchange and may increase the depth of compression and decrease the melting point to improve the formability of the glass composition. However, adding too much K₂O may cause the surface compressive stress and melting point to be too low. Accordingly, in embodiments, the amount of K₂O added to the glass composition may be limited. In embodiments, the glass composition may comprise greater than or equal to 0 mol % and less than or equal to 5 mol % K₂O. In embodiments, concentration of K₂O in the glass composition may be greater than or equal to 0 mol, greater than or equal to 1 mol %, or even greater than or equal to 2 mol %. In embodiments, the concentration of K₂O in the glass composition may be less than or equal to 5 mol % or even less than or equal to 4.5 mol %. In embodiments, the concentration of K₂O in the glass composition may be greater than or equal to 0 mol % and less than or equal to 5 mol %, greater than or equal to 0 mol % and less than or equal to 4.5 mol %, greater than or equal to 1 mol % and less than or equal to 5 mol %, greater than or equal to 1 mol % and less than or equal to 4.5 mol %, greater than or equal to 2 mol % and less than or equal to 5 mol %, or even greater than or equal to 2 mol % and less than or equal to 4.5 mol %, or any and all sub-ranges formed from any of these endpoints. In embodiments, the glass composition may be free or substantially free of K₂O.

In addition to aiding in ion-exchangeability of the glass composition, Li₂O decreases the melting point and improves formability of the glass composition. In embodiments, the glass composition may comprise greater than or equal to 0 mol % and less than or equal to 3 mol % Li₂O. In embodiments, the concentration of Li₂O in the glass composition may be greater than or equal to 0 mol %, greater than or equal to 0.5 mol %, or even greater than or equal to 1 mol %. In embodiments, the concentration of Li₂O in the glass composition may be less than or equal to 3 mol % or even less than or equal to 2 mol %. In embodiments, the concentration of Li₂O in the glass composition may be greater than or equal to 0 mol % and less than or equal to 3 mol %, greater than or equal to 0 mol % and less than or equal to 2 mol %, greater than or equal to 0.5 mol % and less than or equal to 3 mol %, greater than or equal to 0.5 mol % and less than or equal to 2 mol %, greater than or equal to 1 mol % and less than or equal to 3 mol %, or even greater than or equal to 1 mol % and less than or equal to 2 mol %, or any and all sub-ranges and formed from any of these endpoints. In embodiments, the glass composition may be free or substantially free of Li₂O.

As used herein, R₂O is the sum (in mol %) of Na₂O, K₂O, and Li₂O (i.e., R₂O═Na₂O (mol %)+K₂O (mol %)+Li₂O (mol %) present in the glass compositions. Alkali oxides, such as Na₂O, K₂O, and Li₂O, aid in decreasing the softening point and molding temperature of the glass composition, thereby offsetting the increase in the softening point and molding temperature of the glass composition due to higher amounts of SiO₂ in the glass composition, for example. The decrease in the softening point and molding temperature may be further reduced by including combinations of alkali oxides (e.g., two or more alkali oxides) in the glass composition, a phenomenon referred to as the “mixed alkali effect.” However, it has been found that if the amount of alkali oxide is too high, the average coefficient of thermal expansion of the glass composition increases to greater than 100×10⁻⁷/° C., which may be undesirable.

In embodiments, the concentration of R₂O in the glass composition may be greater than or equal to 9 mol % and less than or equal to 19 mol %. In embodiments, the concentration of R₂O in the glass composition may be greater than or equal to 9.5 mol % and less than or equal to 18.5 mol %. In embodiments, the concentration of R₂O in the glass composition may be greater than or equal to 9 mol %, greater than or equal to 9.5 mol %, greater than or equal to 10 mol %, greater than or equal to 10.5 mol %, greater than or equal to 11 mol %, greater than or equal to 11.5 mol %, or even greater than or equal to 12 mol %. In embodiments, the concentration of R₂O in the glass composition may be less than or equal to 19 mol %, less than or equal to 18.5 mol %, less than or equal to 18 mol %, less than or equal to 17.5 mol %, or even less than or equal to 17 mol %. In embodiments, the concentration of R₂O in the glass composition may be greater than or equal to 9 mol % and less than or equal to 18.5 mol %, greater than or equal to 9 mol % and less than or equal to 18 mol %, greater than or equal to 9 mol % and less than or equal to 17.5 mol %, greater than or equal to 9 mol % and less than or equal to 17 mol %, greater than or equal to 9.5 mol % and less than or equal to 18.5 mol %, greater than or equal to 9.5 mol % and less than or equal to 18 mol %, greater than or equal to 9.5 mol % and less than or equal to 17.5 mol %, greater than or equal to 9.5 mol % and less than or equal to 17 mol %, greater than or equal to 10 mol % and less than or equal to 18.5 mol %, greater than or equal to 10 mol % and less than or equal to 18 mol %, greater than or equal to 10 mol % and less than or equal to 17.5 mol %, greater than or equal to 10 mol % and less than or equal to 17 mol %, greater than or equal to 10.5 mol % and less than or equal to 18.5 mol %, greater than or equal to 10.5 mol % and less than or equal to 18 mol %, greater than or equal to 10.5 mol % and less than or equal to 17.5 mol %, greater than or equal to 10.5 mol % and less than or equal to 17 mol %, greater than or equal to 11 mol % and less than or equal to 18.5 mol %, greater than or equal to 11 mol % and less than or equal to 18 mol %, greater than or equal to 11 mol % and less than or equal to 17.5 mol %, greater than or equal to 11 mol % and less than or equal to 17 mol %, greater than or equal to 11.5 mol % and less than or equal to 18.5 mol %, greater than or equal to 11.5 mol % and less than or equal to 18 mol %, greater than or equal to 11.5 mol % and less than or equal to 17.5 mol %, greater than or equal to 11.5 mol % and less than or equal to 17 mol %, greater than or equal to 12 mol % and less than or equal to 18.5 mol %, greater than or equal to 12 mol % and less than or equal to 18 mol %, greater than or equal to 12 mol % and less than or equal to 17.5 mol %, or even greater than or equal to 12 mol % and less than or equal to 17 mol %, or any and all sub-ranges formed from any of these endpoints.

In embodiments, the ratio of the difference in R₂O and Al₂O₃ to B₂O₃ (i.e., (R₂O (mol %)-Al₂O₃(mol %))/B₂O₃ (mol %)) in the glass composition is less than or equal to 0.25 to ensure that the boron is in a three-coordinated state. In embodiments, (R₂O—Al₂O₃)/B₂O₃ in the glass composition may be greater than or equal to −0.15 and less than or equal to 0.25. In embodiments, (R₂O—Al₂O₃)/B₂O₃ in the glass composition may be greater than or equal to −0.05 and less than or equal to 0.2. In embodiments, (R₂O—Al₂O₃)/B₂O₃ in the glass composition may be less than or equal to 0.25 or even less than or equal to 0.2. In embodiments, (R₂O—Al₂O₃)/B₂O₃ in the glass composition may be greater than or equal to −0.15, greater than or equal to −0.05, or even greater than or equal to 0. In embodiments, (R₂O—Al₂O₃)/B₂O₃ in the glass composition may be greater than or equal to −0.15 and less than or equal to 0.25, greater than or equal to −0.15 and less than or equal to 0.2, greater than or equal to −0.05 and less than or equal to 0.25, greater than or equal to −0.05 and less than or equal to 0.2, greater than or equal to 0 and less than or equal to 0.25, greater than or equal to 0 and less than or equal to 0.2, or any and all sub-ranges formed from any of these endpoints.

In embodiments, the ratio of R₂O and Al₂O₃ (i.e., R₂O (mol %)/Al₂O₃(mol %)) in the glass composition is greater than or equal to 0.8 and less than or equal to 1.5 to improve meltability and reduce stress relacation after ion-exchange. When R₂O/Al₂O₃ is less than 0.8, the glass composition may become harder to melt and defects (e.g., unmelted raw material) may occur. When R₂O/Al₂O₃ is greater than 1.5, the glass composition may have an excess of non-bridging oxygen, which may cause the strain point to decrease and stress relaxation to occur during the ion-exchange process, leading to a low surface compressive stress. In embodiments, R₂O/Al₂O₃ in the glass composition may be greater than or equal to 0.85 and less than or equal to 1.45. In embodiments, R₂O/Al₂O₃ in the glass composition may be greater than or equal to 0.9 and less than or equal to 1.4. In embodiments, R₂O/Al₂O₃ in the glass composition may be greater than or equal to 0.8, greater than or equal to 0.85, greater than or equal to 0.9, or even greater than or equal to 0.95. In embodiments, R₂O/Al₂O₃ in the glass composition may be less than or equal to 1.5, less than or equal to 1.45, less than or equal to 1.4, less than or equal to 1.35, or even less than or equal to 1.3. In embodiments, R₂O/Al₂O₃ in the glass composition may be greater than or equal to 0.8 and less than or equal to 1.5, greater than or equal to 0.8 and less than or equal to 1.45, greater than or equal to 0.8 and less than or equal to 1.4, greater than or equal to 0.8 and less than or equal to 1.35, greater than or equal to 0.8 and less than or equal to 1.3, greater than or equal to 0.85 and less than or equal to 1.5, greater than or equal to 0.85 and less than or equal to 1.45, greater than or equal to 0.85 and less than or equal to 1.4, greater than or equal to 0.85 and less than or equal to 1.35, greater than or equal to 0.85 and less than or equal to 1.3, greater than or equal to 0.9 and less than or equal to 1.5, greater than or equal to 0.9 and less than or equal to 1.45, greater than or equal to 0.9 and less than or equal to 1.4, greater than or equal to 0.9 and less than or equal to 1.35, greater than or equal to 0.9 and less than or equal to 1.3, greater than or equal to 0.95 and less than or equal to 1.5, greater than or equal to 0.95 and less than or equal to 1.45, greater than or equal to 0.95 and less than or equal to 1.4, greater than or equal to 0.95 and less than or equal to 1.35, or even greater than or equal to 0.95 and less than or equal to 1.3, or any and all sub-ranges formed from any of these endpoints.

The glass compositions described herein may further comprise P₂O₅. P₂O₅ may decrease the Young's modulus of the glass composition, which helps to reduce the central tension and stress intensity of a glass article formed therefrom. P₂O₅ may also lower the melting and liquidus temperatures and may increase inter-ionic diffusivity such that the time required for ion-exchange is reduced. In embodiments, the glass composition may comprise greater than or equal to 0 mol % and less than or equal to 5 mol % P₂O₅. In embodiments, the concentration of P₂O₅ in the glass composition may be greater than or equal to 0 mol %, greater than or equal to 1 mol %, greater than or equal to 2 mol %, or even greater than or equal to 3 mol %. In embodiments, the concentration of P₂O₅ in the glass composition may be less than or equal to 5 mol % or even less than or equal to 4 mol %. In embodiments, the concentration of P₂O₅ in the glass composition may be greater than or equal to 0 mol % and less than or equal to 5 mol %, greater than or equal to 0 mol % and less than or equal to 4 mol %, greater than or equal to 1 mol % and less than or equal to 5 mol %, greater than or equal to 1 mol % and less than or equal to 4 mol %, greater than or equal to 2 mol % and less than or equal to 5 mol %, greater than or equal to 2 mol % and less than or equal to 4 mol %, greater than or equal to 3 mol % and less than or equal to 5 mol %, or even greater than or equal to 3 mol % and less than or equal to 4 mol %, or any and all sub-ranges formed from any of these endpoints. In embodiments, the glass composition may be free or substantially free of P₂O₅.

In embodiments, the glass compositions described herein may further comprise MgO. In embodiments, the glass composition may comprise less than or equal to 2 mol % MgO. In embodiments, the concentration of MgO in the glass composition may be greater than or equal to 0 mol % or even greater than or equal to 0.5 mol %. In embodiments, the concentration of MgO in the glass composition may be less than or equal to 2 mol % or even less than or equal to 1 mol %. In embodiments, the concentration of MgO in the glass composition may be greater than or equal to 0 mol % and less than or equal to 2 mol %, greater than or equal to 0 mol % and less than or equal to 1 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass composition may be free or substantially free of MgO.

In embodiments, the glass compositions described herein may further comprise CaO. In embodiments, the glass composition may comprise less than or equal to 2 mol % CaO. In embodiments, the concentration of CaO in the glass composition may be greater than or equal to 0 mol % or even greater than or equal to 0.5 mol %. In embodiments, the concentration of CaO in the glass composition may be less than or equal to 2 mol % or even less than or equal to 1 mol %. In embodiments, the concentration of CaO in the glass composition may be greater than or equal to 0 mol % and less than or equal to 2 mol %, greater than or equal to 0 mol % and less than or equal to 1 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass composition may be free or substantially free of CaO.

In embodiments, the glass compositions described herein may further comprise ZnO. In embodiments, the glass composition may comprise less than or equal to 2 mol % ZnO. In embodiments, the concentration of ZnO in the glass composition may be greater than or equal to 0 mol % or even greater than or equal to 0.5 mol %. In embodiments, the concentration of ZnO in the glass composition may be less than or equal to 2 mol % or even less than or equal to 1 mol %. In embodiments, the concentration of ZnO in the glass composition may be greater than or equal to 0 mol % and less than or equal to 2 mol %, greater than or equal to 0 mol % and less than or equal to 1 mol %, greater than or equal to 0.5 mol % and less than or equal to 2 mol %, or even greater than or equal to 0.5 mol % and less than or equal to 1 mol %, or any and all sub-ranges formed from any of these endpoints. In embodiments, the glass composition may be free or substantially free of ZnO.

In embodiments, the glass compositions described herein may further comprise ZrO₂. In embodiments, the glass composition may comprise less than or equal to 1 mol % ZrO₂. In embodiments, the concentration of ZrO₂ in the glass composition may be greater than or equal to 0 mol % or even greater than or equal to 0.5 mol %. In embodiments, the concentration of ZrO₂ in the glass composition may be greater than or equal to 0 mol % and less than or equal to 1 mol %, or even greater than or equal to 0 mol % and less than or equal to 0.5 mol %, or any and all sub-ranges formed from any of these endpoints. In embodiments, the glass composition may be free or substantially free of ZrO₂.

In embodiments, the glass composition may be free or substantially free of components that undesirable increase the Young's modulus of the glass composition, such as MgO, CaO, ZnO, ZrO₂, or combinations thereof.

In embodiments, the glass compositions described herein may further include one or more fining agents. In embodiments, the fining agents may include, for example, SnO₂. In embodiments, the concentration of SnO₂ in the glass composition may be greater than or equal to 0 mol % and less than or equal to 0.1 mol %. In embodiments, the glass composition may be free or substantially free of SnO₂.

In embodiments, the glass compositions described herein may further include tramp materials such as TiO₂, MnO, MoO₃, WO₃, Y₂O₃, CdO, As₂O₃, Sb₂O₃, sulfur-based compounds, such as sulfates, halogens, or combinations thereof. In embodiments, the glass compositions and may be free or substantially free of individual tramp materials, a combination of tramp materials, or all tramp materials. For example, in embodiments, the glass compositions may be free or substantially free of TiO₂, MnO, MoO₃, WO₃, Y₂O₃, CdO, As₂O₃, Sb₂O₃, sulfur-based compounds, such as sulfates, halogens, or combinations thereof.

In embodiments, the glass composition described herein may be free or substantially free of Li₂O, MgO, CaO, ZnO, ZrO₂, or combinations thereof.

In embodiments, the glass composition may have a Young's modulus greater than or equal to 40 GPa and less than or equal to 70 GPa. In embodiments, the glass composition may have a Young's modulus greater than or equal to 45 GPa and less than or equal to 68 GPa. In embodiments, the glass composition may have a Young's modulus greater than or equal to 40 GPa, greater than or equal to 45 GPa, or even greater than or equal to 50 GPa. In embodiments, the glass composition may have a Young's modulus less than or equal to 70 GPa, less than or equal to 68 GPa, less than or equal to 66 GPa, less than or equal to 64 GPa, less than or equal to 62 GPa, or even less than or equal to 60 GPa. In embodiments, the glass composition may have a Young's modulus greater than or equal to 40 GPa and less than or equal to 70 GPa, greater than or equal to 40 GPa and less than or equal to 68 GPa, greater than or equal to 40 GPa and less than or equal to 66 GPa, greater than or equal to 40 GPa and less than or equal to 64 GPa, greater than or equal to 40 GPa and less than or equal to 62 GPa, greater than or equal to 40 GPa and less than or equal to 60 GPa, greater than or equal to 45 GPa and less than or equal to 70 GPa, greater than or equal to 45 GPa and less than or equal to 68 GPa, greater than or equal to 45 GPa and less than or equal to 66 GPa, greater than or equal to 45 GPa and less than or equal to 64 GPa, greater than or equal to 45 GPa and less than or equal to 62 GPa, greater than or equal to 45 GPa and less than or equal to 60 GPa, greater than or equal to 50 GPa and less than or equal to 70 GPa, greater than or equal to 50 GPa and less than or equal to 68 GPa, greater than or equal to 50 GPa and less than or equal to 66 GPa, greater than or equal to 50 GPa and less than or equal to 64 GPa, greater than or equal to 50 GPa and less than or equal to 62 GPa, or even greater than or equal to 50 GPa and less than or equal to 60 GPa, or any and all sub-ranges formed from any of these endpoints.

In embodiments, the glass composition may have a liquidus viscosity greater than or equal to 50 kP. In embodiments, the glass composition may have a liquidus viscosity greater than or equal to 50 kP, greater than or equal to 100 kP, greater than or equal to 250 kP, or even greater than or equal to 500 kP. In embodiments, the glass composition may have a liquidus viscosity less than or equal to 5500 kP, less than or equal to 2500 kP, or even less than or equal to 1000 kP. In embodiments, the glass composition may have a liquidus viscosity greater than or equal to 50 kP and less than or equal to 5500 kP, greater than or equal to 50 kP and less than or equal to 2500 kP, greater than or equal to 50 kP and less than or equal to 1000 kP, greater than or equal to 100 kP and less than or equal to 5500 kP, greater than or equal to 100 kP and less than or equal to 2500 kP, greater than or equal to 100 kP and less than or equal to 1000 kP, greater than or equal to 250 kP and less than or equal to 5500 kP, greater than or equal to 250 kP and less than or equal to 2500 kP, greater than or equal to 250 kP and less than or equal to 1000 kP, greater than or equal to 500 kP and less than or equal to 5500 kP, greater than or equal to 500 kP and less than or equal to 2500 kP, or even greater than or equal to 500 kP and less than or equal to 1000 kP, or any and all sub-ranges formed from any of these endpoints. These ranges of viscosities allow the glass compositions to be formed into sheets by a variety of different techniques including, without limitation, fusion forming, slot draw, floating, rolling, and other sheet-forming processes known to those in the art. However, it should be understood that other processes may be used for forming other articles (i.e., other than sheets).

In embodiments, the glass composition may have a liquidus temperature greater than or equal to 650° C., greater than or equal to 700° C., or even greater than or equal to 750° C. In embodiments, the glass composition may have a liquidus temperature less than or equal to 900° C., less than or equal to 850° C., or even less than or than or equal to 800° C. In embodiments, the glass composition may have a liquidus temperature greater than or equal to 650° C. and less than or equal to 900° C., greater than or equal to 650° C. and less than or equal to 850° C., greater than or equal to 650° C. and less than or equal to 800° C., greater than or equal to 700° C. and less than or equal to 900° C., greater than or equal to 700° C. and less than or equal to 850° C., greater than or equal to 700° C. and less than or equal to 800° C., greater than or equal to 750° C. and less than or equal to 900° C., greater than or equal to 750° C. and less than or equal to 850° C., or even greater than or equal to 750° C. and less than or equal to 800° C., or any and all sub-ranges formed from any of these endpoints.

In embodiments, the glass composition may have a density greater than or equal to 2.2 g/cm³ or even greater than or equal to 2.3 g/cm³. In embodiments, the glass composition may have a density less than or equal to 2.5 g/cm³ or even greater than or equal to 2.4 g/cm³. In embodiments, the glass composition may have a density greater than or equal to 2.2 g/cm³ and less than or equal to 2.5 g/cm³, greater than or equal to 2.2 g/cm³ and less than or equal to 2.4 g/cm³, greater than or equal to 2.3 g/cm³ and less than or equal to 2.5 g/cm³, or even greater than or equal to 2.3 g/cm³ and less than or equal to 2.4 g/cm³, or any and all sub-ranges formed from any of these endpoints.

In embodiments, the glass composition may have a CTE greater than or equal to 6 ppm, greater than or equal to 6 ppm, greater than or equal to 7 ppm, or even greater than or equal to 7 ppm. In embodiments, the glass composition may have a CTE less than or equal to 11 ppm, less than or equal to 10 ppm, or even less than or equal to 8 ppm. In embodiments, the glass composition may have a CTE greater than or equal to 6 ppm and less than or equal to 11 ppm, greater than or equal to 6 ppm and less than or equal 10 ppm, greater than or equal to 6 ppm and less than or equal to 9 ppm, greater than or equal to 7 ppm and less than or equal to 11 ppm, greater than or equal to 7 ppm and less than or equal 10 ppm, greater than or equal to 7 ppm and less than or equal to 9 ppm, greater than or equal to 8 ppm and less than or equal to 11 ppm, greater than or equal to 8 ppm and less than or equal 10 ppm, or even greater than or equal to 8 ppm and less than or equal to 9 ppm, or any and all sub-ranges formed from any of these endpoints.

In embodiments, the glass composition may have a strain point greater than or equal to 400° C., greater than or equal to 425° C., or even greater than or equal to 450° C. In embodiments, the glass composition may have a strain point less than or equal to 600° C., less than or equal to 575° C., or even greater than or equal to 550° C. In embodiments, the glass composition may have a strain point greater than or equal to 400° C. and less than or equal to 600° C., greater than or equal to 400° C. and less than or equal to 575° C., greater than or equal to 400° C. and less than or equal to 550° C., greater than or equal to 425° C. and less than or equal to 600° C., greater than or equal to 425° C. and less than or equal to 575° C., greater than or equal to 425° C. and less than or equal to 550° C., greater than or equal to 450° C. and less than or equal to 600° C., greater than or equal to 450° C. and less than or equal to 575° C., or even greater than or equal to 450° C. and less than or equal to 550° C., or any and all sub-ranges formed from any of these endpoints.

In embodiments, the glass composition may have an annealing point greater than or equal to 425° C., greater than or equal to 450° C., or even greater than or equal to 475° C. In embodiments, the glass composition may have an annealing point less than or equal to 625° C., less than or equal to 600° C., or even less than or equal to 575° C. In embodiments, the glass composition may have an annealing point greater than or equal to 425° C. and less than or equal to 625° C., greater than or equal to 425° C. and less than or equal to 600° C., greater than or equal to 425° C. and less than or equal to 575° C., greater than or equal to 450° C. and less than or equal to 625° C., greater than or equal to 450° C. and less than or equal to 600° C., greater than or equal to 450° C. and less than or equal to 575° C., greater than or equal to 475° C. and less than or equal to 625° C., greater than or equal to 475° C. and less than or equal to 600° C., or even greater than or equal to 475° C. and less than or equal to 575° C., or any and all sub-ranges formed from any of these endpoints.

In embodiments, the glass composition may have a softening point greater than or equal to 625° C., greater than or equal to 650° C., or even greater than or equal to 675° C. In embodiments, the glass composition may have a softening point less than or equal to 875° C., less than or equal to 850° C., or even less than or equal to 825° C. In embodiments, the glass composition may have a softening point greater than or equal to 625° C. and less than or equal to 875° C., greater than or equal to 625° ° C. and less than or equal to 850° C., greater than or equal to 625° C. and less than or equal to 825° C., greater than or equal to 650° C. and less than or equal to 875° C., greater than or equal to 650° C. and less than or equal to 850° C., greater than or equal to 650° C. and less than or equal to 825° C., greater than or equal to 675° C. and less than or equal to 875° C., greater than or equal to 675° C. and less than or equal to 850° C., or even greater than or equal to 675° C. and less than or equal to 825° ° C., or any and all sub-ranges formed from any of these endpoints.

In embodiments, the glass composition may have a Poisson's ratio greater than or equal to 0.2, greater than or equal to 0.22, or even greater than or equal to 0.24. In embodiments, the glass composition may have a Poisson's ratio less than or equal to 0.3, less than or equal to 0.28, or even less than or equal to 0.26. In embodiments, the glass composition may have a Poisson's ratio greater than or equal to 0.2 and less than or equal to 0.3, greater than or equal to 0.2 and less than or equal to 0.28, greater than or equal to 0.2 and less than or equal to 0.26, greater than or equal to 0.22 and less than or equal to 0.3, greater than or equal to 0.22 and less than or equal to 0.28, greater than or equal to 0.22 and less than or equal to 0.26, greater than or equal to 0.24 and less than or equal to 0.3, greater than or equal to 0.24 and less than or equal to 0.28, or even greater than or equal to 0.24 and less than or equal to 0.26, or any and all sub-ranges formed from any of these endpoints.

In embodiments, the glass composition may comprise a shear modulus greater than or equal to 15 GPa, greater than or equal to 18 GPa, or even greater than or equal to 20 GPa. In embodiments, the glass composition may comprise a shear modulus less than or equal to 28 GPa, less than or equal to 26 GPa, or even less than or equal to 24 GPa. In embodiments, the glass composition may comprise a shear modulus greater than or equal to 15 GPa and less than or equal to 28 GPa, greater than or equal to 15 GPa and less than or equal to 26 GPa, greater than or equal to 15 GPa and less than or equal to 24 GPa, greater than or equal to 18 GPa and less than or equal to 28 GPa, greater than or equal to 18 GPa and less than or equal to 26 GPa, greater than or equal to 18 GPa and less than or equal to 24 GPa, greater than or equal to 20 GPa and less than or equal to 28 GPa, greater than or equal to 20 GPa and less than or equal to 26 GPa, or even greater than or equal to 20 GPa and less than or equal to 24 GPa, or any and all sub-ranges formed from any of these endpoints.

In embodiments, the glass composition may have a fracture toughness greater than or equal to 0.5 MPa·m^{1/2} or even greater than or equal to 0.6 MPa·m^{1/2}. In embodiments, the glass composition may have a fracture toughness less than or equal to 0.8 MPa·m^{1/2} or even less than or equal to 0.7 MPa·m^{1/2}. In embodiments, the glass composition may have a fracture toughness greater than or equal to 0.5 MPa·m^{1/2} and less than or equal to 0.8 MPa·m^{1/2}, greater than or equal to 0.5 MPa·m^{1/2} and less than or equal to 0.7 MPa·m^{1/2}, greater than or equal to 0.6 MPa·m^{1/2} and less than or equal to 0.8 MPa·m^{1/2}, or even greater than or equal to 0.6 MPa·m^{1/2} and less than or equal to 0.7 MPa·m^{1/2}, or any and all sub-ranges formed from any of these endpoints.

In embodiments, the glass composition may have a VFT A greater than or −3.75 and less than or equal to 0, a VFT B greater than or equal to 3700 and less than or equal to 9100, and a VFT Tₒ greater than or equal to −75 and less than or equal to 250.

In embodiments, the glass composition may have a 200 Poise temperature greater than or equal to 1250° C. or even greater than or equal to 1350° C. In embodiments, the glass composition may have a 200 Poise temperature less than or equal to 1600° C. or even greater than or equal to 1500° C. In embodiments, the glass composition may have a 200 Poise temperature greater than or equal to 1250° ° C. and less than or equal to 1600° C., greater than or equal to 1250° C. and less than or equal to 1500° C., greater than or equal to 1350° C. and less than or equal to 1600° C., or even greater than or equal to 1350° C. and less than or equal to 1500° C., or any and all sub-ranges formed from any of these endpoints.

In embodiments, the glass composition may have a 35 k Poise temperature greater than or equal to 800° C. or even greater than or equal to 900° C. In embodiments, the glass composition may have a 35 k Poise temperature less than or equal to 1200° C. or even less than or equal to 1100° C. In embodiments, the glass composition may have a 35 k Poise temperature greater than or equal to 800° C. and less than or equal to 1200° C., greater than or equal to 800° C. and less than or equal to 1100° C., greater than or equal to 900° C. and less than or equal to 1200° C., or even greater than or equal to 900° C. and less than or equal to 1100° C., or any and all sub-ranges formed from any of these endpoints.

In embodiments, the glass composition may have a 100 k Poise temperature greater than or equal to 800° C. or even greater than or equal to 900° C. In embodiments, the glass composition may have a 100 k Poise temperature less than or equal to 1200° C. or even less than or equal to 1100° C. In embodiments, the glass composition may have a 100 k Poise temperature greater than or equal to 800° C. and less than or equal to 1200° ° C., greater than or equal to 800° C. and less than or equal to 1100° ° C., greater than or equal to 900° C. and less than or equal to 1200° C., or even greater than or equal to 900° C. and less than or equal to 1100° C., or any and all sub-ranges formed from any of these endpoints.

In embodiments, the process for making a glass article includes heat treating the glass composition at one or more preselected temperatures for one or more preselected times to induce glass homogenization. In embodiments, the heat treatment for making a glass article may include (i) heating a glass composition at a rate of 1-100 C/min to glass homogenization temperature; (ii) maintaining the glass composition at the glass homogenization temperature for a time greater than or equal to 0.25 hour and less than or equal to 4 hours to produce a glass article; and (iii) cooling the formed glass article to room temperature. In embodiments, the glass homogenization temperature may be greater than or equal to 300° C. and less than or equal to 700° C.

In embodiments, the glass compositions described herein are ion-exchangeable to facilitate strengthening the glass article made from the glass compositions. In typical ion-exchange processes, smaller metal ions in the glass compositions are replaced or “exchanged” with larger metal ions of the same valence within a layer that is close to the outer surface of the glass article made from the glass composition. The replacement of smaller ions with larger ions creates a compressive stress within the layer of the glass article made from the glass composition. In embodiments, the metal ions are monovalent metal ions (e.g., Li⁺, Na⁺, K⁺, and the like), and ion-exchange is accomplished by immersing the glass article made from the glass composition in a bath comprising at least one molten salt of the larger metal ion that is to replace the smaller metal ion in the glass article. Alternatively, other monovalent ions such as Ag⁺, TI⁺, Cu⁺, and the like may be exchanged for monovalent ions. The ion-exchange process or processes that are used to strengthen the glass article made from the glass composition may include, but are not limited to, immersion in a single bath or multiple baths of like or different compositions with washing and/or annealing steps between immersions.

Upon exposure to the glass composition, the ion-exchange solution (e.g., KNO₃ and/or NaNO₃ molten salt bath) may, according to embodiments, be at a temperature greater than or equal to 350° C. and less than or equal to 500° C., greater than or equal to 360° C. and less than or equal to 450° C., greater than or equal to 370° C. and less than or equal to 440° C., greater than or equal to 360° C. and less than or equal to 420° ° C., greater than or equal to 370° C. and less than or equal to 400° C., greater than or equal to 375° C. and less than or equal to 475° C., greater than or equal to 400° C. and less than or equal to 500° C., greater than or equal to 410° C. and less than or equal to 490° C., greater than or equal to 420° C. and less than or equal to 480° C., greater than or equal to 430° C. and less than or equal to 470° C., or even greater than or equal to 440° C. and less than or equal to 460° C., or any and all sub-ranges between the foregoing values. In embodiments, the glass composition may be exposed to the ion-exchange solution for a duration greater than or equal to 2 hours and less than or equal to 48 hours, greater than or equal to 2 hours and less than or equal to 24 hours, greater than or equal to 2 hours and less than or equal to 12 hours, greater than or equal to 2 hours and less than or equal to 6 hours, greater than or equal to 8 hours and less than or equal to 44 hours, greater than or equal to 12 hours and less than or equal to 40 hours, greater than or equal to 16 hours and less than or equal to 36 hours, greater than or equal to 20 hours and less than or equal to 32 hours, or even greater than or equal to 24 hours and less than or equal to 28 hours, or any and all sub-ranges between the foregoing values.

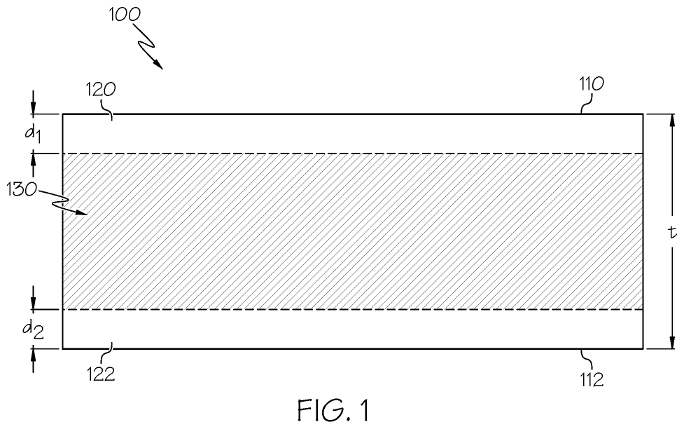

Referring now to FIG. 1, a planar, ion-exchanged glass article is shown at 100. Glass article 100 has a thickness t, a first surface 110, and a second surface 120. The glass articles formed from the glass compositions described herein may be any suitable thickness, which may vary depending on the particular application for use of the glass composition. In embodiments, the glass article 100 may have a thickness t greater than or equal to 10 μm and less than or equal to 500 μm, greater than or equal to 10 μm and less than or equal to 400 μm, greater than or equal to 10 μm and less than or equal to 300 μm, greater than or equal to 10 μm and less than or equal to 200 μm, greater than or equal to 10 μm and less than or equal to 100 μm, greater than or equal to 25 μm and less than or equal to 500 μm, greater than or equal to 25 μm and less than or equal to 400 μm, greater than or equal to 25 μm and less than or equal to 300 μm, greater than or equal to 25 μm and less than or equal to 200 μm, greater than or equal to 25 μm and less than or equal to 100 μm, greater than or equal to 35 μm and less than or equal to 500 μm, greater than or equal to 35 μm and less than or equal to 400 μm, greater than or equal to 35 μm and less than or equal to 300 μm, greater than or equal to 35 μm and less than or equal to 200 μm, or even greater than or equal to 35 μm and less than or equal to 100 μm, or any and all sub-ranges formed from any of these endpoints. While the embodiment shown in FIG. 1 depicts glass article 100 as a flat, planar sheet or plate, the glass article may have any other suitable configuration, for example, three dimensional shapes or non-planar configurations.

Ion-exchanged glass article 100 has a first compressive layer 120 extending from first surface 110 to a depth of compression d₁ into the bulk of the glass article 100. In the embodiment shown in FIG. 1, glass article 100 also has a second compressive layer 122 extending from second surface 112 to a second depth of compression d₂. Glass article 100 also has a central region 130 that extends from d₁ to d₂. Central region 130 is under a tensile stress or central tension (CT), which balances or counteracts the compressive stresses of layers 120 and 122. The depth d₁, d₂ of the first and second compressive layer 120, 122 protects the glass article 100 from the propagation of flaws introduced by sharp impact to first and second surfaces 110, 112 of glass article 100, while the compressive stress minimizes the likelihood of a flaw penetrating through the depth d₁, d₂ of the first and second compressive layers 120, 122.

In embodiments, the glass article may have a peak compressive stress greater than or equal to 400 MPa and less than or equal to 900 MPa. In embodiments, the glass article may have a peak compressive stress greater than or equal to 450 MPa and less than or equal to 600 MPa. In embodiments, the glass article may have a peak compressive stress greater than or equal to 400 MPa, greater than or equal to 450 MPa, greater than or equal to 500 MP, or even greater than or equal to 550 MPa. In embodiments, the glass article may have a peak compressive stress less than or equal to 900 MPa, less than or equal to 800 MPa, less than or equal to 700 MPa, or even less than or equal to 600 MPa. In embodiments, the glass article may have a peak compressive stress greater than or equal to 400 MPa and less than or equal to 900 MPa, greater than or equal to 400 MPa and less than or equal to 800 MPa, greater than or equal to 400 MPa and less than or equal to 700 MPa, greater than or equal to 400 MPa and less than or equal to 600 MPa, greater than or equal to 450 MPa and less than or equal to 900 MPa, greater than or equal to 450 MPa and less than or equal to 800 MPa, greater than or equal to 450 MPa and less than or equal to 700 MPa, greater than or equal to 450 MPa and less than or equal to 600 MPa, greater than or equal to 500 MPa and less than or equal to 900 MPa, greater than or equal to 500 MPa and less than or equal to 800 MPa, greater than or equal to 500 MPa and less than or equal to 700 MPa, greater than or equal to 500 MPa and less than or equal to 600 MPa, greater than or equal to 550 MPa and less than or equal to 900 MPa, greater than or equal to 550 MPa and less than or equal to 800 MPa, greater than or equal to 550 MPa and less than or equal to 700 MPa, or even greater than or equal to 550 MPa and less than or equal to 600 MPa, or any and all sub-ranges formed from any of these endpoints.

In embodiments, a glass article made from the glass composition and having a thickness greater than or equal to 35 μm and less than or equal to 400 μm may be ion-exchanged to achieve a depth of compression greater than or equal to 5 μm, greater than or equal to 10 μm, greater than or equal to 15 μm, or even greater than or equal to 20 μm. In embodiments, a glass article made from the glass composition and having a thickness greater than or equal to 35 μm and less than or equal to 400 μm may be ion-exchanged to achieve a depth of compression less than or equal to 40 μm, less than or equal to 35 μm, or even less than or equal to 30 μm. In embodiments, a glass article made from the glass composition and having a thickness greater than or equal to 35 μm and less than or equal to 400 μm may be ion-exchanged to achieve a depth of compression greater than or equal to 5 μm and less than or equal to 40 μm, greater than or equal to 5 μm and less than or equal to 35 μm, greater than or equal to 5 μm and less than or equal to 30 μm, greater than or equal to 10 μm and less than or equal to 40 μm, greater than or equal to 10 μm and less than or equal to 35 μm, greater than or equal to 10 μm and less than or equal to 30 μm, greater than or equal to 15 μm and less than or equal to 40 μm, greater than or equal to 15 μm and less than or equal to 35 μm, greater than or equal to 15 μm and less than or equal to 30 μm, greater than or equal to 20 μm and less than or equal to 40 μm, greater than or equal to 20 μm and less than or equal to 35 μm, or even greater than or equal to 20 μm and less than or equal to 30 μm, or any and all sub-ranges formed from any of these endpoints.

In embodiments, a glass article made from the glass composition may be ion-exchanged to achieve a depth of compression greater than or equal to 5% or even greater than or equal to 10% of a thickness of the glass article. In embodiments, a glass article made from the glass composition may be ion-exchanged to achieve a depth of compression less than or equal to 20% or even less than or equal to 15% of a thickness of the glass article. In embodiments, a glass article made from the glass composition may be ion-exchanged to achieve a depth of compression greater than or equal to 5% and less than or equal to 20%, greater than or equal to 5% and less than or equal to 15%, greater than or equal to 10% and less than or equal to 20%, or even greater than or equal to 10% and less than or equal to 15%, or any and all sub-ranges formed from any of these endpoints, or a thickness of the glass article.

The relative low Young's modulus of the glass compositions described herein may lead to a reduced central tension, which prevents fragmentation of the glass article into small pieces during bending. In embodiments, the glass article made from the glass composition may have a central tension after ion-exchange strengthening greater than or equal to 100 MPa, greater than or equal to 200 MPa, or even greater than or equal to 300 MPa. In embodiments, the glass article made from the glass composition may have a central tension after ion-exchange strengthening less than or equal to 500 MPa, less than or equal to 450 MPa, or even less than or equal to 400 MPa. In embodiments, the glass article made from the glass composition may have a central tension after ion-exchange strengthening greater than or equal to 100 MPa and less than or equal to 500 MPa, greater than or equal to 100 MPa and less than or equal to 450 MPa, greater than or equal to 100 MPa and less than or equal to 400 MPa, greater than or equal to 200 MPa and less than or equal to 500 MPa, greater than or equal to 200 MPa and less than or equal to 450 MPa, greater than or equal to 200 MPa and less than or equal to 400 MPa, greater than or equal to 300 MPa and less than or equal to 500 MPa, greater than or equal to 300 MPa and less than or equal to 450 MPa, or even greater than or equal to 300 MPa and less than or equal to 400 MPa, or any and all sub-ranges formed from any of these endpoints.

The relative low Young's modulus of the glass compositions described herein provides for the formation of ion-exchanged glass articles capable of bending to a tighter (i.e., smaller) bend radius for a given glass thickness.

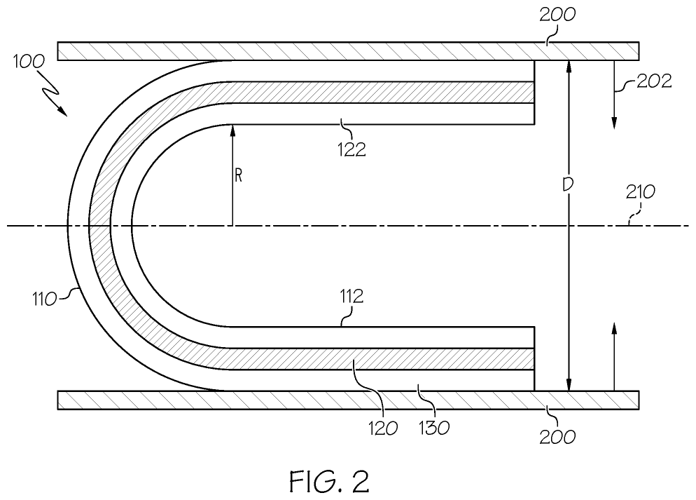

Referring now to FIG. 2, the ion-exchanged glass article 100 is under bend-induced stress. When bent along a fold line 210 with a bend force 202 to a particular bend radius R or to a particular platen distance D, the outer surface 110 of the ion-exchanged glass article 100 is subjected to a tensile stress, induced by the bend, which causes the depth of compression of the compressive layer on the outer surface 110 to decrease to an effective depth of compression, while the inner surface 112 is subjected to additional compressive stress. The effective depth of compression to which the compression on the outer surface 110a increases with increasing bend radii or platen distance or and decreases with decreasing bend radii or platen distance.

When bending an ion-exchanged glass article, the maximum bend-induced tensile stress is given by the equation:

$${σ}_{max} = \frac{E}{1 - {v}^{2}} \cdot \frac{t}{2} \cdot \frac{1}{R} \qquad ( 1 )$$

where σₘₐₓ is the tensile stress on the outer surface of the glass article, E is the Young's modulus of the glass article, v is the Poisson's ratio of the glass article, t is the thickness of the glass article, and R is the bend radius of the outer surface of the glass article. The bend-induced tensile stress may be calculated for various bend radii R by using the Young's modulus and Poisson's ratios (which are dependent upon glass composition and not upon radius). The bend-induced stress may also be calculated for various platen distances D by using the following equation:

D−t=2.396R (2)

where D is platen separation, t is the thickness of the glass article, and R is the bend radius of the outer surface of the glass article.

The closing force F of the bent ion-exchanged glass article is given by the equation:

$$F = \frac{w \cdot t}{6} \cdot \frac{{σ}_{max}^{2}}{E} \qquad ( 3 )$$

where w is the width of the glass article, t is the thickness of the glass article, σₘₐₓ is the tensile stress on the outer surface of the glass article, and E is the Young's modulus of the glass article. Accordingly, when the maximum bend-induced tensile stress is low, the closing force F is also low.

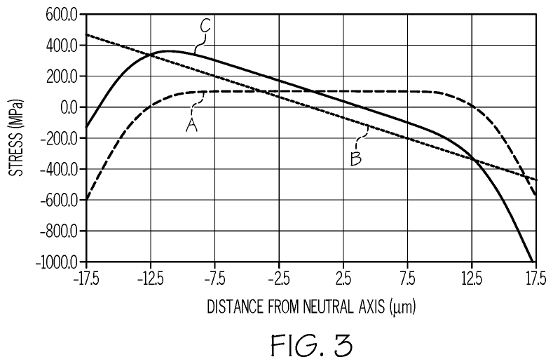

The bend-induced tensile stress may be superimposed with the ion-exchanged stress to yield the net stress profile that exists in the glass article when it is in a bent state (which has an effective depth of compression at the outer surface) for a given platen distance D. FIG. 3 shows the superposition of these stresses determined for a 35 μm thick glass article composed of example glass composition 2 as given in Table 1. As shown in FIG. 3, compressive stress is negative (<0) and tensile stress is positive (>0). Ion-exchanged stress (A), bend-induced tensile stress (B), and the net stress (C) as a function of distance from the neutral axis are plotted. The outer surface of the glass article was bent to a platen distance D of 5.38 mm, at which point the effective depth of the compressive layer at the outer surface is reduced from 4.9 μm to 0.9 μm. The plot of ion-exchanged stress (A) follows a complementary error function, and has a maximum compressive stress of 588 MPa and a depth of compressive layer of 4.9 μm. The plot of bend-induced stress B is linear with distance from the outer to the inner surface and is zero at half the glass article thickness. The superposition of these stresses show that, for a platen distance of 5.38 mm, the effective depth of the compressive layer on the outer surface of the glass article is reduced to 0.9 μm.

In embodiments, an ion-exchanged glass article having an article thickness of 50 μm and bent to a platen spacing of 7.12 mm may have a peak central tension of the bent glass article that may be greater than or equal to 340 MPa and less than or equal to 450 MPa.

The bending forces applied to the glass article may also result in the potential for crack propagation leading to instantaneous or slower, fatigue failure mechanisms. The presence of flaws at the outer surface 100, or just beneath the surface, of the glass article can contribute to these potential failure modes. Using equation (4) below, it is possible to estimate the stress intensity factor in a glass article subjected to bending forces. Equation (4) is given by:

K_{I}=Ω·(σ_{IOX stress profile at depth a}+σ_{bend induced at depth a})·(πα)^{0.5} (4)
where K_{I} is the mode I stress intensity, which refers to crack opening), Ω is the shape factor for the flaw geometry, σ_{IOX stress profile at depth a} is the stress due to ion-exchange at depth a, σ_{bend induced at depth a} is the stress due to bending at depth a, and a is the flaw depth.

For example, for the glass article plotted in FIG. 3, the following inputs would be used: Ω=0.73, σ_{IOX stress profile at depth a}=−426 MPa (negative sign used here for compressive stress), σ_{bend induced at depth a}=440 MPa (positive sign used here for tensile stress), and a=1 μm. With these inputs:

K_{I}=0.72·(−426 MPa+440 MPa)·(π·10⁻⁶m)^{=0.028} MPa·m^{0.5}
which is less than the static fatigue limit of 0.5 MPa·m^{0.5}, the static fatigue limit expected from sodium-containing glasses (Journal of Materials Science, 26 (1991) 5445-5455). Any stress intensity level lower than the static fatigue limit will not exhibit slow crack growth. Therefore, the glass will not fail due to slow crack growth.

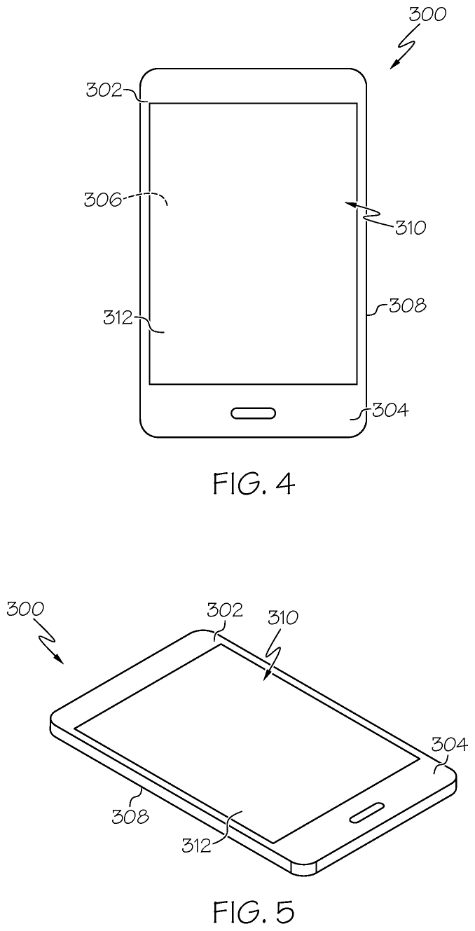

The glass articles disclosed herein may be incorporated into another article such as an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc.), appliance articles, or any article that may benefit from some transparency, scratch-resistance, abrasion resistance or a combination thereof. An exemplary article incorporating any of the glass articles disclosed herein is shown in FIGS. 4 and 5. Specifically, FIGS. 4 and 5 show a consumer electronic device 300 including a housing 302 having front 304, back 306, and side surfaces 308; electrical components (not shown) that are at least partially inside or entirely within the housing and including at least a controller, a memory, and a display 310 at or adjacent to the front surface of the housing; and a cover substrate 312 at or over the front surface of the housing such that it is over the display. In some embodiments, at least one of the cover substrate 312 or a portion of housing 302 may include any of the glass articles disclosed herein.

### Examples

In order that various embodiments be more readily understood, reference is made to the following examples, which are intended to illustrate various embodiments of the glass compositions described herein.

Table 1 shows glass compositions (in terms of mol %) and the respective properties of the glass compositions. Glass articles are formed having the comparative glass composition C1 and example glass compositions 1-11.

TABLE 1

| Example | C1 | 1 | 2 | 3 | 4 | 5 |
|---|---|---|---|---|---|---|
| SiO₂ | 68.95 | 56.16 | 50.89 | 46.14 | 41.26 | 50.69 |
| Al₂O₃ | 10.27 | 15.34 | 15.18 | 15.25 | 15.28 | 10.04 |
| B₂O₃ | 0 | 13.92 | 19.35 | 24.09 | 28.86 | 29.63 |
| P₂O₅ | 0 | 0 | 0 | 0 | 0 | 0 |
| Na₂O | 15.2 | 14.46 | 14.57 | 14.52 | 14.60 | 9.64 |
| K₂O | 0 | 0 | 0 | 0 | 0 | 0 |
| MgO | 5.36 | 0 | 0 | 0 | 0 | 0 |
| CaO | 0.06 | 0 | 0 | 0 | 0 | 0 |
| SnO₂ | 0.17 | 0.09 | 0 | 0 | 0 | 0 |
| R₂O | 15.2 | 14.46 | 14.57 | 14.52 | 14.60 | 9.64 |
| R2O/Al₂O₃ | 1.48 | 0.94 | 0.96 | 0.95 | 0.96 | 0.96 |
| (R₂O—Al₂O₃)/B₂O₃ | — | −0.06 | 0.03 | −0.03 | −0.02 | −0.01 |
| Young's Modulus (GPa) | 71.3 | 59.0 | 56.1 | 53.6 | 51.2 | 48.7 |
| Density (g/cm³) | 2.432 | 2.348 | 2.325 | 2.304 | 2.282 | 2.223 |
| CTE (ppm) | 8.14 | 7.69 | 7.81 | 7.85 | 8.03 | 6.53 |
| Strain Pt. (° C.) | 599 | 518.0 | 487.0 | 463.0 | 450.0 | 431.0 |
| Anneal Pt. (° C.) | 652 | 566.0 | 532.0 | 506.0 | 490.0 | 475.0 |
| Softening Pt. (° C.) | 895.4 | 823.9 | 752.2 | — | 667.0 | 685.3 |
| Poisson's ratio | 0.205 | 0.226 | 0.241 | 0.250 | 0.255 | 0.244 |
| Shear modulus (GPa) | 29.6 | 24.1 | 22.6 | 21.4 | 20.4 | 19.6 |
| K_{Ic} (CN) (MPa · m^{1/2}) | 0.73 | — | 0.653 | 0.674 | 0.678 | 0.658 |
| VFT A | −2.15 | −3.36 | — | — | — | — |
| VFT B | 6405 | 8456 | — | — | — | — |
| VFT Tₒ | 231.8 | 45.2 | — | — | — | — |
| 200 Poise temperature (° C) | 1671 | 1539 | — | — | — | — |
| 35k Poise temperature (° C) | 1189 | 1115 | — | — | — | — |
| 100k Poise temperature (° C) | 1128 | 1057 | — | — | — | — |
| Liquidus temperature (° C) | 1020 | — | — | — | — | — |
| Liquidus Viscosity (kP) | 950 | — | — | — | — | — |
| Example | 6 | 7 | 8 | 9 | 10 | 11 |
| SiO₂ | 50.85 | 51.82 | 47.40 | 41.41 | 51.20 | 42.09 |
| Al₂O₃ | 15.10 | 15.27 | 15.40 | 20.28 | 10.11 | 15.52 |
| B₂O₃ | 19.57 | 14.03 | 18.68 | 19.24 | 19.35 | 18.88 |
| P₂O₅ | 0.00 | 0.00 | 0.00 | 0.00 | 4.88 | 4.92 |
| Na₂O | 9.65 | 14.41 | 14.15 | 14.43 | 14.34 | 14.30 |
| K₂O | 4.72 | 4.36 | 4.27 | 4.54 | 0.01 | 4.19 |
| SnO₂ | 0.11 | 0.11 | 0.10 | 0.10 | 0.11 | 0.11 |
| R₂O | 14.37 | 18.77 | 18.42 | 18.97 | 14.35 | 18.49 |
| R2O/Al₂O₃ | 0.95 | 1.23 | 1.20 | 0.94 | 1.42 | 1.19 |
| (R₂O—Al₂O₃)/B₂O₃ | −0.04 | 0.25 | 0.16 | −0.07 | 0.22 | 0.16 |
| Young's Modulus (GPa) | 54.6 | 65.2 | 60.5 | 57.1 | 56.9 | 56.1 |
| Density (g/cm³) | 2.319 | 2.412 | 2.377 | 2.367 | 2.331 | 2.362 |
| CTE (ppm) | 8.79 | 10.21 | 10.06 | 10.24 | 8.08 | 10.28 |
| Strain Pt. (° C.) | 459.4 | 492.4 | 477.2 | 470.5 | 459.7 | 449.5 |
| Anneal Pt. (° C.) | 508.3 | 532.3 | 517.9 | 516.9 | 499.5 | 490.0 |
| Softening Pt. (° C.) | — | — | — | — | — | — |
| Poisson's ratio | 0.241 | 0.231 | 0.240 | 0.251 | 0.227 | 0.239 |
| Shear modulus (GPa) | 22.0 | 26.5 | 24.4 | 22.8 | 23.2 | 22.6 |
| K_{Ic} (CN) (MPa · m^{1/2}) | — | — | — | — | — | — |
| VFT A | −3.65 | −2.14 | −1.07 | −3.42 | −1.26 | −1.56 |
| VFT B | 9087 | 6318 | 3734 | 7484 | 3880 | 4346 |
| VFT Tₒ | −69.3 | 31.8 | 241.7 | 38.7 | 223.8 | 172.1 |
| 200 Poise temperature (° C) | 1458 | 1454 | 1349 | 1347 | 1313 | 1297 |
| 35k Poise temperature (° C) | 1040 | 977 | 907 | 979 | 892 | 884 |
| 100k Poise temperature (° C) | 981 | 917 | 857 | 928 | 844 | 834 |
| Liquidus temperature (° C) | <835 | 790 | 720 | <900 | <830 | <790 |
| Liquidus Viscosity (kP) | >2,514 | 1,558 | 5,447 | >186 | >138 | >296 |

Referring now to Table 2, the maximum bend-induced tensile stress and closing force was calculated for as-made glass articles (i.e., not ion-exchanged) formed from comparative glass composition C1 and example glass compositions 1-11, using Equations (1) and (3) and assuming a thickness t of 35 μm, a width w of 100 mm, and a platen spacing D of 5.38 mm. The glass articles made from example glass composition 1-11 had a lower maximum bend-induced tensile stress and closing force than a glass article made from comparative glass composition C1. As indicated by Table 2, low-modulus glass compositions as described herein have a relatively lower maximum bend-induced tensile stress and closing force such that the glass articles formed therefrom may be more easily folded or flexed.

TABLE 2

| Example | C1 | 1 | 2 | 3 | 4 | 5 |
|---|---|---|---|---|---|---|
| σₘₐₓ (MPa) | 584 | 488 | 467 | 449 | 430 | 407 |
| Closing force (N) | 2.8 | 2.4 | 2.3 | 2.2 | 2.1 | 2.0 |
| Example | 6 | 7 | 8 | 9 | 10 | 11 |
| σₘₐₓ (MPa) | 455 | 541 | 504 | 478 | 471 | 467 |
| Closing force (N) | 2.2 | 2.6 | 2.4 | 2.3 | 2.3 | 2.3 |

Referring now to Table 3, glass articles formed from example glass compositions 1-11 having a length of 2.54 cm, a width of 2.54 cm, and a thickness of 0.8 mm were immersed in a molten salt bath comprised of 100 wt % KNO₃ at the listed temperature for the listed time period. The compressive stress CS and depth of compression DOC values listed in Table 3 were measured by FSM.

TABLE 3

| | | | | | | |
|---|---|---|---|---|---|---|
| Example | 1 | 2 | 3 | 4 | 5 | 6 |

IOX: 370° C. for 4 hrs.

| | | | | | | |
|---|---|---|---|---|---|---|
| CS (MPa) | — | 734 | 643 | — | — | 496 |
| DOC (μm) | — | 6.7 | 5.8 | — | — | 12.7 |

IOX: 370° C. for 9 hrs.

| | | | | | | |
|---|---|---|---|---|---|---|
| CS (MPa) | — | 681 | 605 | 558 | — | 481 |
| DOC (μm) | — | 11.1 | 8.9 | 6.5 | — | 18.1 |

IOX: 370° C. for 16 hrs.

| | | | | | | |
|---|---|---|---|---|---|---|
| CS (MPa) | — | 651 | 563 | 502 | 360 | 451 |
| DOC (μm) | — | 14.4 | 11.2 | 9.1 | 6.2 | 24.1 |

IOX: 380° C. for 2 hrs.

| | | | | | | |
|---|---|---|---|---|---|---|
| CS (MPa) | 715 | — | — | — | — | — |
| DOC (μm) | 12.2 | — | — | — | — | — |

IOX: 380° C. for 6 hrs.

| | | | | | | |
|---|---|---|---|---|---|---|
| CS (MPa) | 645 | — | — | — | — | — |
| DOC (μm) | 20.3 | — | — | — | — | — |

IOX: 410° C. for 0.5 hrs.

| | | | | | | |
|---|---|---|---|---|---|---|
| CS (MPa) | — | — | — | — | — | 720 |
| DOC (μm) | — | — | — | — | — | 12.3 |

IOX: 410° C. for 1 hr.

| | | | | | | |
|---|---|---|---|---|---|---|
| CS (MPa) | — | — | — | — | — | 702 |
| DOC (μm) | — | — | — | — | — | 17.3 |

IOX: 410° C. for 2 hrs.

| | | | | | | |
|---|---|---|---|---|---|---|
| CS (MPa) | — | — | — | — | — | 667 |
| DOC (μm | — | — | — | — | — | 23.3 |

| | | | | | |
|---|---|---|---|---|---|
| Example | 7 | 8 | 9 | 10 | 11 |

IOX: 370° C. for 4 hrs.

| | | | | | |
|---|---|---|---|---|---|
| CS (MPa) | 876 | 791 | 710 | 569 | 619 |
| DOC (μm) | 14.1 | 12.4 | 12.6 | 10.1 | 18.1 |

IOX: 370° C. for 9 hrs.

| | | | | | |
|---|---|---|---|---|---|
| CS (MPa) | 870 | 765 | 702 | 521 | 578 |
| DOC (μm) | 21.8 | 19.9 | 18.3 | 14.3 | 27.1 |

IOX: 370° C. for 16 hrs.

| | | | | | |
|---|---|---|---|---|---|
| CS (MPa) | 852 | 731 | 657 | 489 | 534 |
| DOC (μm) | 29.5 | 25.8 | 26.1 | 19.3 | 35.8 |

IOX: 380° C. for 2 hrs.

| | | | | | |
|---|---|---|---|---|---|
| CS (MPa) | — | — | — | — | — |
| DOC (μm) | — | — | — | — | — |

IOX: 380° C. for 6 hrs.

| | | | | | |
|---|---|---|---|---|---|
| CS (MPa) | — | — | — | — | — |
| DOC (μm) | — | — | — | — | — |

IOX: 410° C. for 0.5 hrs.

| | | | | | |
|---|---|---|---|---|---|
| CS (MPa) | 650 | 604 | 720 | — | — |
| DOL (μm) | 11.9 | 12.5 | 12.3 | — | — |

IOX: 410° C. for 1 hr.

| | | | | | |
|---|---|---|---|---|---|
| CS (MPa) | 596 | 570 | 702 | — | — |
| DOL (μm) | 15.8 | 16.2 | 17.3 | — | — |

IOX: 410° C. for 2 hrs.

| | | | | | |
|---|---|---|---|---|---|
| CS (MPa) | 551.1 | 538.7 | 667 | — | — |
| DOL (μm) | 21.8 | 22.6 | 23.3 | — | — |

As indicated by Table 3, glass articles formed from the low-modulus glass compositions described herein may be ion-exchange to achieved a desired DOL (e.g., less than or equal to 20% of the thickness of the glass article) to enable tighter bending without cracking and/or failure.

Referring now to Table 4, plots of the ion-exchanged stress, bend-induced tensile stress, and net stress (e.g., FIG. 3) for glass articles formed from the compositions and having the thicknesses t shown in Table 4 and at a platen distance D of 5.38 mm were generated. The peak compressive stress CS and depth of compression DOC values from the plots are shown in Table 4. Peak compressive stress CS values generally decrease 10% to 20% from 0.8 mm thick glass articles to 0.05 mm (i.e., 50 μm) thick glass articles.

Referring now to Table 5, the maximum central tension CTₘₐₓ and stress intensity K_{I} with 1 μm flaw size after ion-exchange for each composition and thickness t shown in Table 4 is reported in Table 5. The maximum CTₘₐₓ values reported in Table 5 were approximated by the product of a peak compressive stress and a depth of compression divided by the difference between the thickness of the glass article and twice the depth of compression, wherein the compressive stress and depth of compression were measured by FSM. Stress intensity K_{I} was calculated using Equation 4.

The platen distance D values shown in Table 5 are the “safe bending” platen spacing for an ion-exchanged glass article composed of comparative example glass composition C1 and assuming a 1 μm flaw depth. A “safe bending” platen distance was considered to be when the net stress at the depth of a flaw is equal to zero, such that the bend-induced tensile stress compensates for the ion-exchanged stress.

TABLE 4

| | Example | C1 | 1 | 2 | 3 | 4 | 5 |
|---|---|---|---|---|---|---|---|
| t = 35 μm | CS (MPa) | 750 | — | 588 | 514 | 446 | 288 |
| | DOL (μm) | 7.1 | — | 6.7 | 5.8 | 6.5 | 6.2 |
| t = 50 μm | CS (MPa) | 750 | 572 | 545 | 484 | 402 | — |
| | DOL (μm) | 9.8 | 12.2 | 11.1 | 8.9 | 9.1 | — |
| t = 75 μm | CS (MPa) | 800 | 572 | 521 | — | — | — |
| | DOL (μm) | 15.3 | 12.2 | 14.4 | — | — | — |
| t = 100 μm | CS (MPa) | 830 | 516 | — | — | — | — |
| | DOL (μm) | 16.2 | 20.3 | — | — | — | — |
| | Example | 6 | 7 | 8 | 9 | 10 | 11 |
| t = 35 μm | CS (MPa) | — | 556 | 523 | 489 | — | — |
| | DOL (μm) | — | 6.5 | 6.1 | 6.3 | — | — |
| t = 50 μm | CS (MPa) | — | 562 | 509 | 479 | 455 | — |
| | DOL (μm) | — | 9.8 | 9.8 | 10.2 | 10.1 | — |
| t = 75 μm | CS (MPa) | — | 564 | 489 | 458 | 417 | — |
| | DOL (μm) | — | 15.0 | 15.2 | 16.0 | 14.3 | — |
| t = 100 μm | CS (MPa) | 385 | 551 | 441 | 439 | 391 | 495 |
| | DOL (μm) | 18.1 | 20.6 | 21.8 | 19.9 | 19.3 | 18.1 |

TABLE 5

| | Example | C1 | 1 | 2 | 3 | 4 | 5 |
|---|---|---|---|---|---|---|---|
| t = 35 μm | CTₘₐₓ (MPa) | 452 | — | 362 | 352 | 326 | 302 |
| D = 5.38 mm | K_{I} (MPa · m^{0.5}) | — | — | 0.03 | 0.14 | 0.17 | 6.20.37 |
| t = 50 μm | CTₘₐₓ (MPa) | 483 | 383 | 372 | 369 | 346 | — |
| D = 7.12 mm | K_{I} (MPa · m^{0.5}) | | 0.05 | 0.07 | 0.17 | 0.25 | — |
| t = 75 μm | CTₘₐₓ (MPa) | 540 | 461 | 425 | — | — | — |
| D = 9.39 mm | K_{I} (MPa · m^{0.5}) | | 0.20 | 0.21 | — | — | — |
| t = 100 μm | CTₘₐₓ (MPa) | 586 | 454 | — | — | — | — |
| D = 12 mm | K_{I} (MPa · m^{0.5}) | | 0.30 | — | — | — | — |
| | Example | 6 | 7 | 8 | 9 | 10 | 11 |
| t = 35 μm | CTₘₐₓ (MPa) | — | 409 | 386 | 363 | — | — |
| D = 5.38 mm | K_{I} (MPa · m^{0.5}) | — | 0.22 | 0.22 | 0.21 | — | — |
| t = 50 μm | CTₘₐₓ (MPa) | — | 433 | 403 | 379 | 372 | — |
| D = 7.12 mm | K_{I} (MPa · m^{0.5}) | — | 0.21 | 0.22 | 0.21 | 0.24 | — |
| t = 75 μm | CTₘₐₓ (MPa) | — | 485 | 448 | 420 | 422 | — |
| D = 9.39 mm | K_{I} (MPa · m^{0.5}) | — | 0.31 | 0.36 | 0.34 | 0.41 | — |
| t = 100 μm | CTₘₐₓ (MPa) | 429 | 500 | 455 | 443 | 438 | 446 |
| D = 12 mm | K_{I} (MPa · m^{0.5}) | 0.46 | 0.37 | 0.47 | 0.42 | 0.49 | 0.29 |

As shown in Table 5, glass articles formed from example glass compositions 1-11 had a relatively reduced CTₘₐₓ as compared to a glass article formed from comparative glass composition C1. Assuming a 1 μm flaw depth, the stress intensity K_{I} for each of the example glass compositions was lower than 0.5 MPa·m^{0.5}, which is less than the static fatigue limit that would be expected from sodium-containing glasses. As exemplified by Tables 4 and 5, glass articles formed from the glass compositions described herein have a relatively reduced maximum central tension CTₘₐₓ, which prevents fragmentation of the glass article into small pieces upon being bent, and reduced stress intensity K_{I}, which prevents crack growth and glass failure.

Referring now to Table 6, plots of the ion-exchanged stress, bend-induced tensile stress, and net stress (e.g., FIG. 3) for glass articles formed from the compositions shown in Table 6 having a thickness of a thickness t of 400 μm and at a bend radius R of 50 mm were generated. The peak compressive stress CS, the maximum central tension CTₘₐₓ, reduced depth of compression DOC (i.e., where stress=0), and flaw depth for stress intensity K_{I}=0.5 MPa·m^{0.5} are reported in Table 6.

TABLE 6

| Example | C1 | 1 | 2 | 6 | 7 | 8 |
|---|---|---|---|---|---|---|
| CS (MPa) | 940 | 645 | 651 | 451 | 852 | 731 |
| DOC (μm) | 21.7 | 20.3 | 14.4 | 24.1 | 29.5 | 25.8 |
| Reduced DOC (μm) | 10.6 | 8.7 | 6.5 | 7.8 | 14.1 | 11.7 |
| (Stress = 0) | | | | | | |
| Flaw depth (μm) for KI = 0.5 | 12.4 | 11.1 | 8.5 | 11.2 | 16.4 | 14.2 |
| MPa · m^{0.5} | | | | | | |
| CTₘₐₓ (MPa) | 290 | 237 | 230 | 214 | 268 | 246 |

| Example | 9 | 10 | 11 |
|---|---|---|---|
| CS (MPa) | 657 | 489 | 534 |
| DOC (μm) | 26.1 | 19 | 35.8 |
| Reduced DOC (μm) | 11.4 | 6.6 | 13.4 |
| (Stress = 0) | | | |
| Flaw depth (μm) for KI = 0.5 | 14.1 | 9.4 | 17 |
| MPa · m^{0.5} | | | |
| CTₘₐₓ (MPa) | 232 | 225 | 218 |

For some bending glass applications (e.g., auto-interior application), a relatively thicker glass articles having a thickness t, for example, of 400 μm may be bent to a 50 mm radius. These thicker glass articles may be required to have a relatively deeper reduced depth of compression DOC. Using Equation (4), the largest flaw depth at which the glass article cannot fail (i.e., by not exceeding their expected fatigue limit 0.5 MPa·m^{0.5}) was calculated. Glass articles formed from example glass compositions 7-9 and 11 were able to withhold a larger flaw size than the glass article formed from comparative glass composition C1, while having a relatively reduced central tension CTₘₐₓ.

It will be apparent to those skilled in the art that various modifications and variations may be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

1. A glass composition comprising:
greater than or equal to 40 mol % and less than or equal to 56.5 mol % SiO₂;
greater than or equal to 10 mol % and less than or equal to 25 mol % Al₂O₃;
greater than or equal to 12 mol % and less than or equal to 35 mol % B₂O₃;
greater than or equal to 9 mol % and less than or equal to 14.75 mol % Na₂O;
greater than or equal to 0 mol % and less than or equal to 5 mol % K₂O; and
greater than or equal to 0 mol % and less than or equal to 3 mol % Li₂O, wherein
R₂O is greater than or equal to 9 mol % and less than or equal to 19 mol %, wherein R₂O is the sum of Na₂O, K₂O, and Li₂O;
(R₂O—Al₂O₃)/B₂O₃ is less than or equal to 0.25; and
R₂O/Al₂O₃ is greater than or equal to 0.8 and less than or equal to 1.5.

2. The glass composition of claim 1, wherein the glass composition comprises greater than or equal to 13 mol % and less than or equal to 30 mol % B₂O₃.

3. The glass composition of claim 1, wherein the glass composition comprises greater than or equal to 9.5 mol % and less than or equal to 14.5 mol % Na₂O.

4. The glass composition of claim 1, wherein the glass composition comprises greater than or equal to 10.5 mol % and less than or equal to 23 mol % Al₂O₃.

5. The glass composition of claim 1, wherein (R₂O—Al₂O₃)/B₂O₃ is greater than or equal to −0.15 and less than or equal to 0.25.

6. The glass composition of claim 1, wherein R₂O/Al₂O₃ is greater than or equal to 0.85 and less than or equal to 1.45.

7. The glass composition of claim 1, wherein R₂O is greater than or equal to 9.5 mol % and less than or equal to 18.5 mol %.

8. The glass composition of claim 1, wherein the glass composition comprises greater than or equal to 0 mol % and less than or equal to 5 mol % P₂O₅.

9. The glass composition of claim 1, wherein the glass composition is free or substantially free of Li₂O, MgO, CaO, ZnO, ZrO₂, or combinations thereof.

10. The glass composition of claim 1, wherein the glass composition comprises greater than or equal to 0 mol % and less than or equal to 0.1 mol % SnO₂.

11. An ion-exchanged glass article comprising:
greater than or equal to 40 mol % and less than or equal to 56.5 mol % SiO₂;
greater than or equal to 10 mol % and less than or equal to 25 mol % Al₂O₃;
greater than or equal to 12 mol % and less than or equal to 35 mol % B₂O₃;
greater than or equal to 9 mol % and less than or equal to 14.75 mol % Na₂O;
greater than or equal to 0 mol % and less than or equal to 5 mol % K₂O; and
greater than or equal to 0 mol % and less than or equal to 3 mol % Li₂O, wherein
R₂O is greater than or equal to 9 mol % and less than or equal to 19 mol %, wherein R₂O is the sum of Na₂O, K₂O, and Li₂O;
(R₂O—Al₂O₃)/B₂O₃ is less than or equal to 0.25;
R₂O/Al₂O₃ is greater than or equal to 0.8 and less than or equal to 1.5; and
a Young's modulus of the glass article, before being ion-exchanged, is greater than or equal to 40 GPa and less than or equal to 70 GPa.

12. The glass article of claim 11, wherein a Young's modulus of the glass article, before being ion-exchanged, is greater than or equal to 45 GPa and less than or equal to 68 GPa.

13. The glass article of claim 11, wherein a liquidus viscosity of the glass article, before being ion-exchanged, is greater than or equal to 50 kP.

14. The glass article of claim 11, wherein a peak compressive stress of the glass article is greater than or equal to 400 MPa and less than or equal to 900 MPa.

15. The glass article of claim 11, wherein a thickness of the glass article is greater than or equal to 35 μm and less than or equal to 400 μm and a depth of compression of the glass article is greater than or equal to 5 μm and less than or equal to 40 μm.

16. The glass article of claim 11, wherein a depth of compression of the glass article is greater than or equal to 5% and less than or equal to 20% of a thickness of the glass article.

17. The glass article of claim 11, wherein a peak central tension of the glass article is greater than or equal to 200 MPa and less than or equal to 450 MPa.

18. The glass article of claim 11, wherein the glass article is bent to a platen spacing of 7.12 mm and a peak central tension of the bent glass article is greater than or equal to 340 MPa and less than or equal to 450 MPa at an article thickness of 50 μm.

19. A consumer electronic device, comprising:
a housing having a front surface, a back surface, and side surfaces;
electrical components provided at least partially within the housing, the electrical components including at least a controller, a memory, and a display, the display being provided at or adjacent the front surface of the housing; and
the glass article of claim 11, disposed over the display.

20. A method of strengthening a glass article, the method comprising:
immersing the glass article in an ion-exchange solution, the glass article comprising:
greater than or equal to 40 mol % and less than or equal to 56.5 mol % SiO₂;
greater than or equal to 10 mol % and less than or equal to 25 mol % Al₂O₃;
greater than or equal to 12 mol % and less than or equal to 35 mol % B₂O₃;
greater than or equal to 9 mol % and less than or equal to 14.75 mol % Na₂O;
greater than or equal to 0 mol % and less than or equal to 5 mol % K₂O; and
greater than or equal to 0 mol % and less than or equal to 3 mol % Li₂O, wherein
R₂O is greater than or equal to 9 mol % and less than or equal to 19 mol %, wherein R₂O is the sum of Na₂O, K₂O, and Li₂O;
(R₂O—Al₂O₃)/B₂O₃ is less than or equal to 0.25; and
R₂O/Al₂O₃ is greater than or equal to 0.8 and less than or equal to 1.5;
ion-exchanging the glass article in the ion-exchange solution for a time period greater than or equal to 1 hour and less than or equal to 24 hours at a temperature greater than or equal to 350° C. and less than or equal to 480° C. to achieve a compressive stress layer extending from a surface of the glass article to a depth of compression and comprising a peak compressive stress value in a range of 400 MPa to 900 MPa.
